(19) United States
(12) Patent Application Publication
(10) Pub. No.: US 2025/0366176 A1
(43) Pub. Date: Nov. 27, 2025

(54) THREE DIMENSIONAL INTEGRATED CIRCUIT AND FABRICATION THEREOF

(71) Applicants: TAIWAN SEMICONDUCTOR MANUFACTURING COMPANY, LTD., Hsinchu (TW); National Yang Ming Chiao Tung University, Hsinchu City (TW)

(72) Inventors: Chenming HU, Oakland, CA (US); Kuan-Neng CHEN, Hsinchu City (TW); Po-Tsang HUANG, Hsinchu City (TW); Hao-Tung CHUNG, Taoyuan City (TW); Bo-Jheng SHIH, Kaohsiung City (TW); Yu-Ming PAN, New Taipei City (TW)

(73) Assignees: TAIWAN SEMICONDUCTOR MANUFACTURING COMPANY, LTD., Hsinchu (TW); National Yang Ming Chiao Tung University, Hsinchu City (TW)

(21) Appl. No.: 19/295,249

(22) Filed: Aug. 8, 2025

Related U.S. Application Data
(62) Division of application No. 17/843,195, filed on Jun. 17, 2022.

(51) Int. Cl. H10D 84/83; H01L 23/522; H01L 23/528; H10D 30/01; H10D 30/62

(52) U.S. Cl. CPC H10D 84/834; H01L 23/5226; H01L 23/5283; H10D 30/024; H10D 30/6211

(57) ABSTRACT

An IC structure includes a first transistor, a dielectric layer, a plurality of semiconductor pillars, a plurality of semiconductor plugs, a semiconductor structure, and a second transistor. The first transistor is formed on a substrate. The dielectric layer is above the first transistor. The semiconductor pillars extend from the substrate into the dielectric layer. The semiconductor plugs extend from a top surface of the dielectric layer into the dielectric layer to the plurality of semiconductor pillars. The semiconductor structure is disposed over the top surface of the dielectric layer. The second transistor is formed on the semiconductor structure.

### PRIORITY CLAIM AND CROSS-REFERENCE

This application is a divisional application of U.S. application Ser. No. 17/843,195, filed Jun. 17, 2022, which is herein incorporated by reference in its entirety.

### BACKGROUND

The semiconductor industry has experienced rapid growth due to continuous improvements in the integration density of various electronic components (i.e., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-9 illustrate intermediate stages of a method of forming a 3D IC structure in accordance with some embodiments.

FIG. 10 illustrates an exemplary cross-sectional view of a 3D IC according to some other embodiments of the present disclosure.

FIGS. 11A-19 illustrate intermediate stages of a method of forming a 3D IC structure in accordance with some embodiments.

FIG. 20 illustrates an exemplary cross-sectional view of a 3D IC according to some other embodiments of the present disclosure.

FIGS. 21-28 illustrate intermediate stages of a method of forming a 3D IC structure in accordance with some embodiments.

FIG. 29 illustrates an exemplary cross-sectional view of a 3D IC according to some other embodiments of the present disclosure.

FIGS. 30A-38 illustrate intermediate stages of a method of forming a 3D IC structure in accordance with some embodiments.

FIG. 39 illustrates an exemplary cross-sectional view of a 3D IC according to some other embodiments of the present disclosure.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Integrated circuit (IC) devices integration improvements are essentially two-dimensional (2D) in nature, in that the volume occupied by the integrated components is essentially on the surface of the semiconductor wafer. Although dramatic improvement in lithography has resulted in considerable improvement in 2D IC formation, there are physical limits to the density that can be achieved in two dimensions. One of these limits is the minimum size needed to make these components. Also, when more devices are put into one chip, more complex designs are used. Therefore, the present disclosure, in various embodiments, provides a three-dimensional (3D) IC structure having lower transistors at a lower level and higher transistors at a higher level, which in turn significantly improves the device density in a given area.

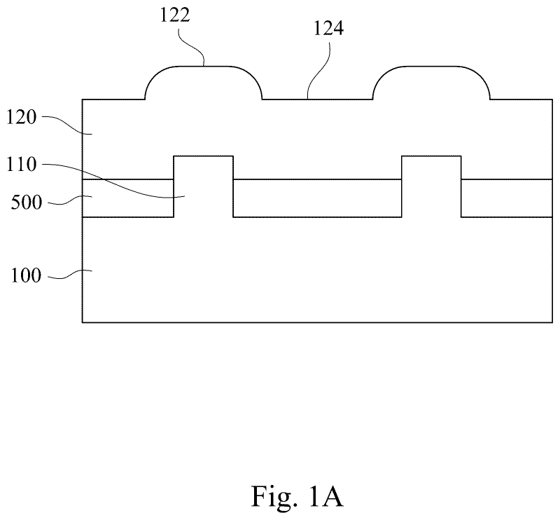

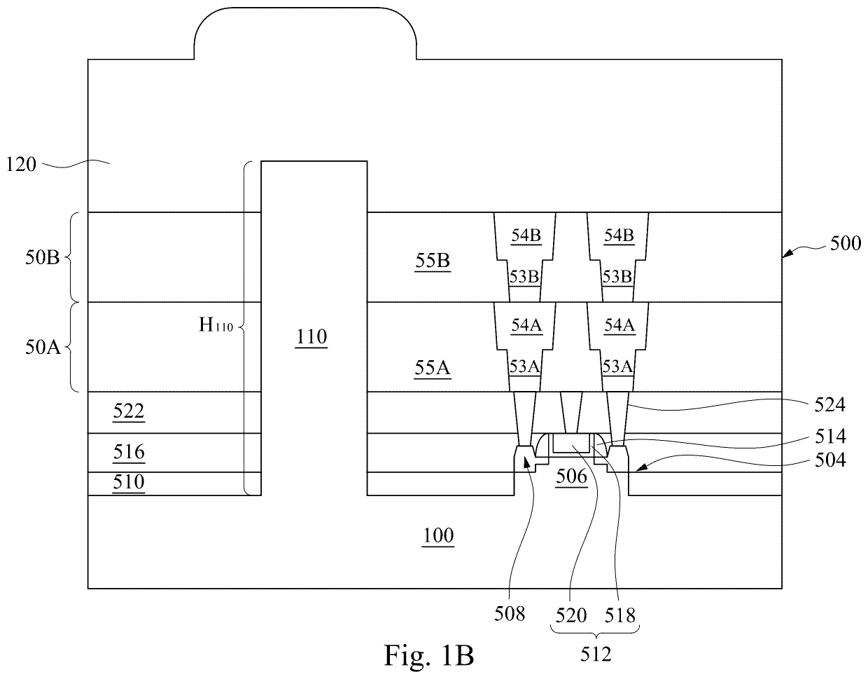

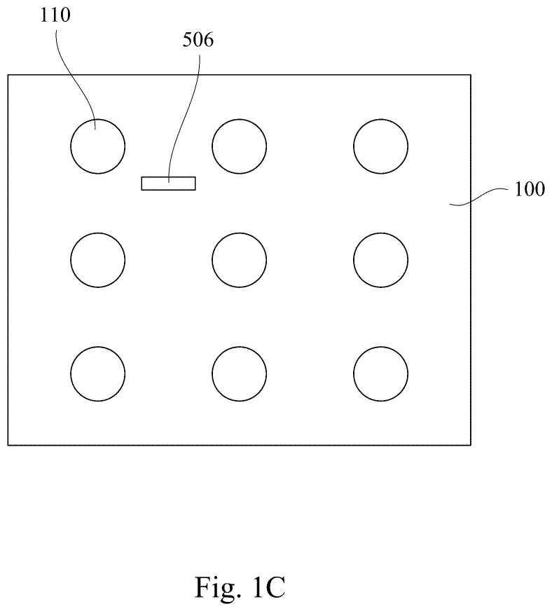

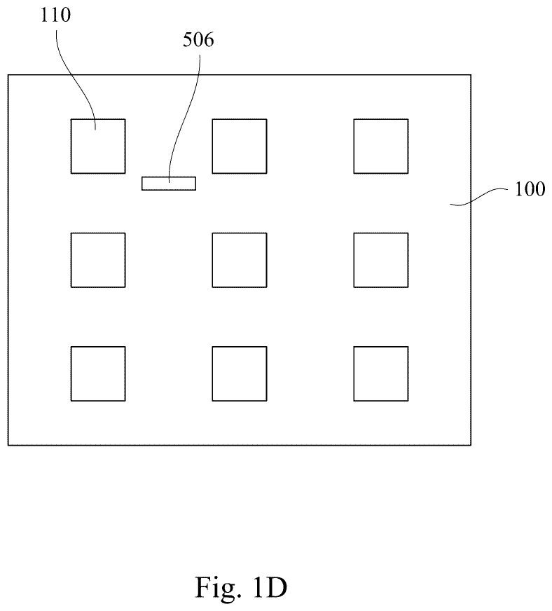

FIGS. 1A-9 illustrate intermediate stages of a method of forming a 3D IC structure in accordance with some embodiments. Although the cross-sectional views shown in FIGS. 1A-9 are described with reference to a method, it will be appreciated that the structures shown in FIGS. 1A-9 are not limited to the method but rather may stand alone separate of the method. Although FIGS. 1A-9 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

FIG. 1A is a cross-sectional view of an example initial structure comprising a semiconductor substrate 100 and a lower-level circuit structure 500 formed over the semiconductor substrate 100. FIG. 1B illustrates a cross-sectional view of an example lower-level circuit structure 500 comprising various electronic devices formed over the substrate 100, and a multilevel interconnect structure (e.g., metallization layers 50A and 50B) formed over the substrate 100, in accordance with some embodiments. Generally, FIG. 1B illustrates a transistor 504 formed on the substrate 100, with multiple interconnection layers formed thereover. Multiple interconnect levels (e.g., a plurality of layers 50B stacked one above another) may be similarly stacked in the fabrication process of an integrated circuit. In the illustrated embodiments, the transistor 504 is a FinFET. In some other embodiments, the transistor 504 is a planar FET, a gate-all-around (GAA) FET, a nanosheet FET, a nanowire FET, or other suitable FET. Transistors 504 and the overlying interconnect wires in the multilevel interconnect structure can be electrically coupled to function as, for example, logic circuits or other circuits.

The substrate 100 may comprise a bulk semiconductor substrate or a silicon-on-insulator (SOI) substrate. An SOI substrate includes an insulator layer below a thin semiconductor layer that is the active layer of the SOI substrate. The semiconductor of the active layer and the bulk semiconductor generally comprise the crystalline semiconductor material silicon, but may include one or more other semiconductor materials such as germanium, silicon-germanium alloys, compound semiconductors (e.g., GaAs, AlAs, InAs, GaN, AlN, and the like), or their alloys (e.g., GaₓAl₁₋ₓAs, GaₓAl₁₋ₓN, InₓGa₁₋ₓAs and the like), or combinations thereof. The semiconductor materials may be doped or undoped. Other substrates that may be used include multi-layered substrates, gradient substrates, or hybrid orientation substrates.

In some embodiments, the FinFET device 504 illustrated in FIG. 1B is a three-dimensional MOSFET structure formed in fin-like strips of semiconductor protrusions 506 referred to as fins. The cross-section shown in FIG. 1B is taken along a longitudinal axis of the fin 506 in a direction parallel to the direction of the current flow between the source and drain regions 508. The fin 506 may be formed by patterning the substrate using photolithography and etching techniques. For example, a spacer image transfer (SIT) patterning technique may be used. In this method a sacrificial layer is formed over a substrate and patterned to form mandrels using suitable photolithography and etch processes. Spacers are formed alongside the mandrels using a self-aligned process. The sacrificial layer is then removed by an appropriate selective etch process. Each remaining spacer may then be used as a hard mask to pattern the respective fin 506 by etching a trench into the substrate 100 using, for example, reactive ion etching (RIE). FIG. 1B illustrates a single fin 506, although the substrate 100 may comprise any number of fins.

Semiconductor pillars 110 are also formed over the semiconductor substrate 100. Because the semiconductor pillars 110 are formed from the single-crystalline semiconductor substrate 100, the semiconductor pillars 110 are single crystalline in nature, and thus the semiconductor pillars 110 can serve as seeds for epitaxially growing a single-crystalline semiconductor material above the lower-level circuit structure 500, as will be discussed in detail below. The semiconductor pillars 110 extend from the substrate 100 to above the lower-level circuit structure 500, and thus the semiconductor pillars 110 have heights much greater than heights of the semiconductor fins 506. For example, a ratio of a height of semiconductor pillar 110 to a height of semiconductor fin 506 is greater than 5, 6, 7, 8, 9, 10, or more. Such a height difference allows for melting a semiconductor material subsequently formed over the lower-level circuit structure 500, while not melting materials of the lower-level circuit structure 500, e.g., semiconductor materials of the transistors 504. In some embodiments, the semiconductor pillar 110 has a height H₁₁₀ in a range from about 0.1 to about 1 μm. In some embodiments, the semiconductor pillar height H₁₁₀ is greater than 200 nm.

In some embodiments, the semiconductor pillars 110 are formed by patterning the substrate 100 using photolithography and etching techniques. The semiconductor pillars 110 may be formed prior to forming semiconductor fins 506. For example, the semiconductor substrate 100 may undergo a first patterning process to form semiconductor pillars 110, and then undergo a second patterning process to form semiconductor fins 506. In this scenario, the semiconductor pillars 110 may be protected using a mask (e.g., photoresist mask or nitride hard mask) before the second patterning process begins, and the mask can be removed after the second patterning process is completed. In some embodiments, the semiconductor pillars 110 are arranged equidistantly in rows and columns, as illustrated in the top view of FIG. 1C. The semiconductor pillars 110 each have a circular or elliptic top-view profile, which is different from the strip-shaped top-view profile of semiconductor fins 506 (only one fin is illustrated for the sake of brevity), as illustrated in the top view of FIG. 1C. In some other embodiments, the semiconductor pillars 110 each have a quadrilateral or square top-view profile, which is different from the strip-shaped top-view profile of semiconductor fins 506, as illustrated in FIG. 1D. The semiconductor pillar 110 has a top-view area different from a top-view area of the semiconductor fin 506.

Shallow trench isolation (STI) regions 510 formed around sidewalls of the fin 506 and the pillar 110 are illustrated in FIG. 1B. STI regions 510 may be formed by depositing one or more dielectric materials (e.g., silicon oxide) to completely fill the trenches around the fins and then recessing the top surface of the dielectric materials. The dielectric materials of the STI regions 510 may be deposited using a high density plasma chemical vapor deposition (HDP-CVD), a low-pressure CVD (LPCVD), sub-atmospheric CVD (SACVD), a flowable CVD (FCVD), spin-on, and/or the like, or a combination thereof. After the deposition, an anneal process or a curing process may be performed. In some cases, the STI regions 510 may include a liner such as, for example, a thermal oxide liner grown by oxidizing the silicon surface. The recess process may use, for example, a planarization process (e.g., a chemical mechanical polish (CMP)) followed by a selective etch process (e.g., a wet etch, or dry etch, or a combination thereof) that may recess the top surface of the dielectric materials in the STI region 510 such that an upper portion of fin 506 and an upper portion of semiconductor pillar 110 protrude from surrounding insulating STI regions 510.

In some embodiments, the gate structure 512 of the FinFET device 504 illustrated in FIG. 1B is a high-k, metal gate (HKMG) gate structure that may be formed using a gate-last process flow. In a gate last process flow a sacrificial dummy gate structure (not shown) is formed after forming the STI regions 510. The dummy gate structure may comprise a dummy gate dielectric, a dummy gate electrode, and a hard mask. First a dummy gate dielectric material (e.g., silicon oxide, silicon nitride, or the like) may be deposited. Next a dummy gate material (e.g., amorphous silicon, polycrystalline silicon, or the like) may be deposited over the dummy gate dielectric. A hard mask layer (e.g., silicon nitride, silicon carbide, or the like) may be formed over the dummy gate material. The dummy gate structure is then formed by patterning the hard mask and transferring that pattern to the dummy gate dielectric and dummy gate material using suitable photolithography and etching techniques. The dummy gate structure may extend along multiple sides of the protruding fins 506 and extend between the fins over the surface of the STI regions 510. As described in greater detail below, the dummy gate structure may be replaced by the HKMG gate structure 512 as illustrated in FIG. 1B. The materials used to form the dummy gate structure and hard mask may be deposited using any suitable method such as CVD, plasma-enhanced CVD (PECVD), atomic layer deposition (ALD), plasma-enhanced ALD (PEALD) or the like, or by thermal oxidation of the semiconductor surface, or combinations thereof.

Source and drain regions (collectively referred to as “source/drain regions” or “S/D regions”) 508 and spacers 514 of FinFET 504, illustrated in FIG. 1B, are formed, for example, self-aligned to the dummy gate structures. Spacers 514 may be formed by deposition and anisotropic etch of a spacer dielectric layer performed after the dummy gate patterning is complete. The spacer dielectric layer may include one or more dielectrics, such as silicon oxide, silicon nitride, silicon oxynitride, silicon carbide, silicon carbonitride, the like, or a combination thereof. The anisotropic etch process removes the spacer dielectric layer from over the top of the dummy gate structures leaving the spacers 514 along the sidewalls of the dummy gate structures.

Source and drain regions 508 are semiconductor regions in direct contact with the semiconductor fin 506. In some embodiments, the source and drain regions 508 may comprise heavily-doped regions and relatively lightly-doped drain extensions, or LDD regions. Generally, the heavily-doped regions are spaced away from the dummy gate structures using the spacers 514, whereas the LDD regions may be formed prior to forming spacers 514 and, hence, extend under the spacers 514 and, in some embodiments, extend further into a portion of the semiconductor fin 506 below the dummy gate structure. The LDD regions may be formed, for example, by implanting dopants (e.g., As, P, B, In, or the like) using an ion implantation process.

In some embodiments, the source and drain regions 508 may comprise an epitaxially grown region. For example, after forming the LDD regions, the spacers 514 may be formed and, subsequently, the heavily-doped source and drain regions may be formed self-aligned to the spacers 514 by first etching the fins 506 to form recesses, and then depositing a crystalline semiconductor material in the recess by a selective epitaxial growth (SEG) process that may fill the recess and, typically, extend beyond the original surface of the fin to form a raised source-drain structure, as illustrated in FIG. 1B. The crystalline semiconductor material may be elemental (e.g., Si, or Ge, or the like), or an alloy (e.g., Si₁₋ₓCₓ, or Si₁₋ₓGeₓ, or the like). The SEG process may use any suitable epitaxial growth method, such as e.g., vapor/solid/liquid phase epitaxy (VPE, SPE, LPE), or metal-organic CVD (MOCVD), or molecular beam epitaxy (MBE), or the like. A high dose (e.g., from about 10¹⁵ cm⁻² to 10¹⁸ cm⁻²) of dopants may be introduced into the heavily-doped source and drain regions 508 either in situ during SEG, or by an ion implantation process performed after the SEG, or by a combination thereof. In some embodiments, the semiconductor pillars 110 may be covered with a mask (e.g., photoresist mask or hard mask) before forming the source/drain regions 508, and then the mask can be removed after the source/drain regions are 508 are formed.

A first interlayer dielectric (ILD) 516 is deposited over the structure. In some embodiments, a contact etch stop layer (CESL) (not shown) of a suitable dielectric (e.g., silicon nitride, silicon carbide, or the like, or a combination thereof) may be deposited prior to depositing the ILD material. A planarization process (e.g., selective etch back) may be performed to remove excess ILD material and any remaining hard mask material from over the dummy gates to form a top surface wherein the top surface of the dummy gate material is exposed and may be substantially coplanar with the top surface of the first ILD 516. The HKMG gate structures 512, illustrated in FIG. 1B, may then be formed by first removing the dummy gate structures using one or more etching techniques, thereby creating trenches between respective spacers 514. Next, a replacement gate dielectric layer 518 comprising one more dielectrics, followed by a replacement conductive gate layer 520 comprising one or more conductive materials, are deposited to completely fill the recesses. Excess portions of the gate structure layers 518 and 520 may be removed from over the top surface of first ILD 516 using, for example, a selective etch back process. The resulting structure, as illustrated in FIG. 1B, may be a substantially coplanar surface comprising an exposed top surface of first ILD 516, spacers 514, and remaining portions of the HKMG gate layers 518 and 520 inlaid between respective spacers 514.

The gate dielectric layer 518 includes, for example, a high-k dielectric material such as oxides and/or silicates of metals (e.g., oxides and/or silicates of Hf, Al, Zr, La, Mg, Ba, Ti, and other metals), silicon nitride, silicon oxide, and the like, or combinations thereof, or multilayers thereof. In some embodiments, the conductive gate layer 520 may be a multilayered metal gate stack comprising a barrier layer, a work function layer, and a gate-fill layer formed successively on top of gate dielectric layer 518. Example materials for a barrier layer include TiN, TaN, Ti, Ta, or the like, or a multilayered combination thereof. A work function layer may include TiN, TaN, Ru, Mo, Al, for a p-type FET, and Ti, Ag, TaAl, TaAIC, TiAIN, TaC, TaCN, TaSiN, Mn, Zr, for an n-type FET. Other suitable work function materials, or combinations, or multilayers thereof may be used. The gate-fill layer which fills the remainder of the recess may comprise metals such as Cu, Al, W, Co, Ru, or the like, or combinations thereof, or multi-layers thereof. The materials used in forming the gate structure may be deposited by any suitable method, e.g., CVD, PECVD, physical vapor deposition (PVD), ALD, PEALD, electrochemical plating (ECP), electroless plating and/or the like.

A second ILD layer 522 may be deposited over the first ILD layer 516, as illustrated in FIG. 1B. In some embodiments, the insulating materials to form the first ILD layer 516 and the second ILD layer 522 may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The dielectric materials used to form the first ILD layer 516 and the second ILD layer 522 may be deposited using any suitable method, such as CVD, physical vapor deposition (PVD), ALD, PEALD, PECVD, SACVD, FCVD, spin-on, and/or the like, or a combination thereof. A selective etch back process may be performed on the deposited ILD layer 522 such that upper portions of semiconductor pillars 110 protrude from the second ILD layer 522.

As illustrated in FIG. 1B, electrodes of electronic devices formed in the substrate 100 may be electrically connected to conductive features of a first interconnect level 50A using conductive connectors (e.g., contacts 524) formed through the intervening dielectric layers. In the embodiment illustrated in FIG. 1B, some contacts 524 make electrical connections to the source and drain regions 508 of FinFETs 504 and can be referred to as source/drain contacts, some contacts 524 make electrical connections to gate structures 512 of FinFETs 504 and can be referred to as gate contacts. The contacts may be formed using photolithography techniques. For example, a patterned mask may be formed over the second ILD 522 and used to etch openings that extend through the second ILD 522 to expose a portion of gate structures 512, as well as etch openings that extend further through the first ILD 516 and the CESL (if present) liner below first ILD 516 to expose portions of the source and drain regions 508.

In some embodiments, a conductive liner may be formed in the openings in the first ILD layer 516 and the second ILD layer 522. Subsequently, the openings are filled with a conductive fill material. The liner comprises barrier metals used to reduce out-diffusion of conductive materials from the contacts 524 into the surrounding dielectric materials. In some embodiments, the liner may comprise two barrier metal layers. The first barrier metal comes in contact with the semiconductor material in the source and drain regions 508 and may be subsequently chemically reacted with the heavily-doped semiconductor in the source and drain regions 508 to form a low resistance ohmic contact, after which the unreacted metal may be removed. For example, if the heavily-doped semiconductor in the source and drain regions 508 is silicon or silicon-germanium alloy semiconductor, then the first barrier metal may comprise Ti, Ni, Pt, Co, other suitable metals, or their alloys. The second barrier metal layer of the conductive liner may additionally include other metals (e.g., TiN, TaN, Ta, or other suitable metals, or their alloys). A conductive fill material (e.g., W, Al, Cu, Ru, Ni, Co, alloys of these, combinations thereof, and the like) may be deposited over the conductive liner layer to fill the contact openings, using any acceptable deposition technique (e.g., CVD, ALD, PEALD, PECVD, PVD, ECP, electroless plating, or the like, or any combination thereof). Next, a selective etch back process may be used to remove excess portions of all the conductive materials from over the surface of the second ILD 522. The resulting conductive plugs extend into the first and second ILD layers 516 and 522 and constitute contacts 524 making physical and electrical connections to the electrodes of electronic devices, such as the tri-gate FinFET 504 illustrated in FIG. 1B.

As illustrated in FIG. 1B, multiple interconnect levels may be formed, stacked vertically above the contact plugs 524 formed in the first and second ILD layers 516 and 522, in accordance with a back end of line (BEOL) scheme adopted for the integrated circuit design. In the BEOL scheme illustrated in FIG. 1B, various interconnect levels have similar features. However, it is understood that other embodiments may utilize alternate integration schemes wherein the various interconnect levels may use different features. For example, the contacts 524, which are shown as vertical connectors, may be extended to form conductive lines which transport current laterally.

In this disclosure, the interconnect level comprises conductive vias and lines embedded in an inter-metal dielectric (IMD) layer. In addition to providing insulation between various conductive elements, an IMD layer may include one or more dielectric etch stop layers to control the etching processes that form openings in the IMD layer. Generally, vias conduct current vertically and are used to electrically connect two conductive features located at vertically adjacent levels, whereas lines conduct current laterally and are used to distribute electrical signals and power within one level. In the BEOL scheme illustrated in FIG. 1B, conductive vias 53A connect contacts 524 to conductive lines 54A and, at subsequent levels, vias connect lower lines to upper lines (e.g., lines 54A and 54B can be connected by via 53B). Other embodiments may adopt a different scheme. For example, vias 53A may be omitted from the second level and the contacts 524 may be configured to be directly connected to lines 54A.

The first interconnect level 50A may be formed using, for example, a dual damascene process flow. First, a dielectric stack used to form IMD layer 55A may be deposited using one or more layers of the dielectric materials listed in the description of the first and second ILD layers 516 and 522. In some embodiments, IMD layer 55A includes an etch stop layer (not shown) positioned at the bottom of the dielectric stack. The etch stop layer comprises one or more insulator layers (e.g., SiN, SiC, SiCN, SiCO, CN, combinations thereof, or the like) having an etch rate different than an etch rate of an overlying material. The techniques used to deposit the dielectric stack for IMD may be the same as those used in forming the first and second ILD layers 516 and 522. In some embodiments, after depositing the dielectric stack for IMD, a selective etch back process may be performed on the deposited dielectric materials such that upper portions of semiconductor pillars 110 protrude from the dielectric materials.

Appropriate photolithography and etching techniques (e.g., anisotropic RIE employing fluorocarbon chemistry) may be used to pattern the IMD layer 55A to form openings for vias and lines. The openings for vias may be vertical holes extending through IMD layer 55A to expose a top conductive surface of contacts 524, and openings for lines may be longitudinal trenches formed in an upper portion of the IMD layer 55A. In some embodiments, the method used to pattern holes and trenches in IMD 55A utilizes a via-first scheme, wherein a first photolithography and etch process form holes for vias, and a second photolithography and etch process form trenches for lines. Other embodiments may use a different method, for example, a trench-first scheme, or an incomplete via-first scheme, or a buried etch stop layer scheme. The etching techniques may utilize multiple steps. For example, a first main etch step may remove a portion of the dielectric material of IMD layer 55A and stop on an etch stop dielectric layer. Then, the etchants may be switched to remove the etch stop layer dielectric materials. The parameters of the various etch steps (e.g., chemical composition, flow rate, and pressure of the gases, reactor power, etc.) may be tuned to produce tapered sidewall profiles with a desired interior taper angle.

Several conductive materials may be deposited to fill the holes and trenches forming the conductive features 53A and 54A of the first interconnect level 50A. The openings may be first lined with a conductive diffusion barrier material and then completely filled with a conductive fill material deposited over the conductive diffusion barrier liner. In some embodiments, a thin conductive seed layer may be deposited over the conductive diffusion barrier liner to help initiate an electrochemical plating (ECP) deposition step that completely fills the openings with a conductive fill material.

The diffusion barrier conductive liner in the vias 53A and lines 54A comprises one or more layers of TaN, Ta, TiN, Ti, Co, or the like, or combinations thereof. The conductive fill layer in the vias 53A and lines 54A may comprise metals such as Cu, Al, W, Co, Ru, or the like, or combinations thereof, or multi-layers thereof. The conductive materials used in forming the conductive features 53A and 54A may be deposited by any suitable method, for example, CVD, PECVD, PVD, ALD, PEALD, ECP, electroless plating and the like. In some embodiments, the conductive seed layer may be of the same conductive material as the conductive fill layer and deposited using a suitable deposition technique (e.g., CVD, PECVD, ALD, PEALD, or PVD, or the like). Any excess conductive material over the IMD 55A outside of the openings may be removed by selective etch back. This step embeds the conductive vias 53A and conductive lines 54A into IMD 55A, as illustrated in FIG. 1B.

The interconnect level positioned vertically above the first interconnect level 50A in FIG. 1B, is the second interconnect level 50B. In some embodiments, the structures of the various interconnect levels (e.g., the first interconnect level 50A and the second interconnect level 50B) may be similar. In the example illustrated in FIG. 1B, the second interconnect level 50B comprises conductive vias 53B and conductive lines 54B embedded in an insulating film IMD 55B having a substantially planar top surface. The materials and processing techniques described above in the context of the first interconnect level 50A may be used to form the second interconnect level 50B and subsequent interconnect levels.

Although an example electronic device (FinFET 504) and example interconnect structures making connections to the electronic device are described, it is understood that one of ordinary skill in the art will appreciate that the above examples are provided for illustrative purposes only to further explain applications of the present embodiments, and are not meant to limit the present embodiments in any manner.

An ILD layer 120 is formed over the lower-level circuit structure 500 using, for example, PVD, CVD, ALD or the like. The ILD layer 120 will be etched to form holes on semiconductor pillars 110 that serve as single crystalline seeds for crystallization of a non-single crystalline semiconductor material, which will be discussed in greater detail below. Therefore, the ILD layer 120 plays a different role than the underlying IMD layers 55A, 55B and ILD layers 516, 522, and thus may have a different thickness and/or material than the IMD layers 55A, 55B and ILD layers 516, 522. For example, the ILD layer 120 may be thicker or thinner than one or more of the IMD layers 55A, 55B and ILD layers 516, 522. Alternatively, the ILD layer 120 may have a same thickness and/or material as one or more of the IMD layers 55A, 55B and ILD layers 516, 522.

In some embodiments, the ILD layer 120 may be made of silicon oxide (SiO₂). In some embodiments, may be made of, for example, phosphosilicate glass (PSG), borophosphosilicate glass (BPSG), fluorosilicate glass (FSG), SiOₓC_{y}, Spin-On-Glass, Spin-On-Polymers, silicon oxynitride, combinations thereof, or the like, formed by any suitable method, such as spin-on coating, chemical vapor deposition (CVD), plasma-enhanced CVD (PECVD), or the like. Because the ILD layer 120 is deposited over an uneven surface having top surfaces of semiconductor pillars 110 higher than a top surface of the lower-level circuit structure 500, the ILD layer 120 has an uneven top surface that includes, for example, raised regions 122 directly above the semiconductor pillars 110, and a lower region 124 directly above the lower-level circuit structure 500.

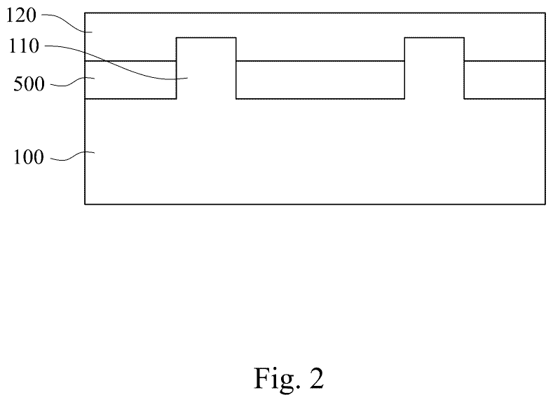

In FIG. 2, a CMP process is performed on the ILD layer 120 to remove the raised regions 122, such that the ILD layer 120 has a substantially planar top surface.

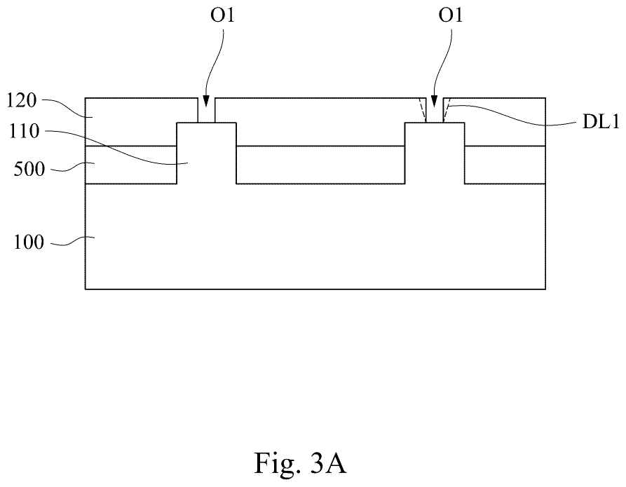

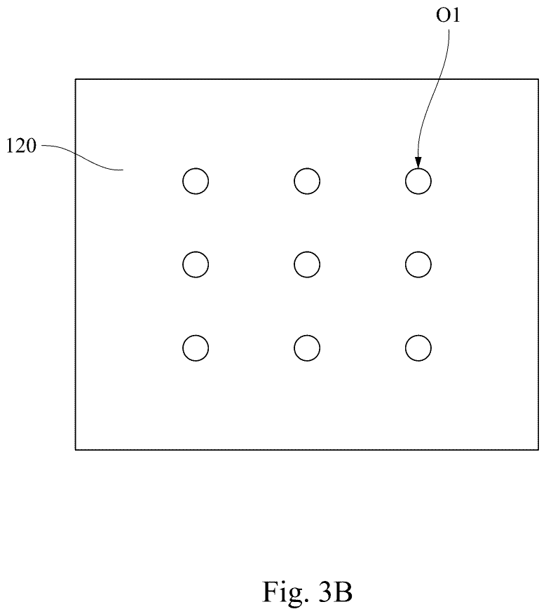

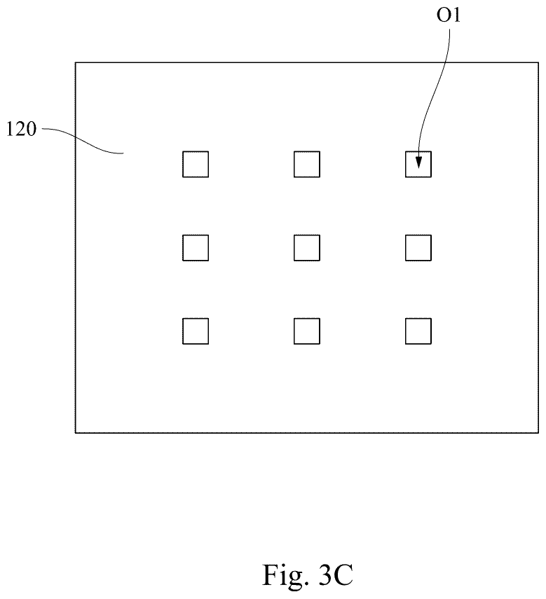

In FIG. 3A, a patterning process is performed on the ILD layer 120 to form holes O1 in the patterned ILD layer 120. The semiconductor pillars 110 are respectively exposed at bottoms of the holes O1. The holes O1 correspond to the semiconductor pillars 110 in one-to-one manner, and thus the holes O1 are also arranged equidistantly in rows and columns, as illustrated in the top views of FIGS. 3B and 3C. In some embodiments, the hole O1 has a vertical dimension (i.e., depth) less than about 1 μm and a lateral dimension (e.g., diameter or width) in a range from about 1 nm to about 1 μm.

The ILD layer 120 is patterned using suitable photolithography and etching techniques. For example, a photoresist layer is formed over the ILD layer 120 by using a spin-on coating process, followed by patterning the photoresist layer to expose target regions of the ILD layer 120 using suitable photolithography techniques. For example, photoresist layer is irradiated (exposed) and developed to remove portions of the photoresist layer. In greater detail, a photomask or reticle (not shown) may be placed above the photoresist layer, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist layer, and a developer may be used to remove either the exposed or unexposed portions of the photoresist material depending on whether a positive or negative resist is used. After the patterned photoresist layer is formed, an etching process is performed on the exposed target regions of the ILD layer 120, thus forming holes O1 in the ILD layer 120. Although the holes O1 illustrated in FIG. 3A have vertical sidewalls, the etching process may lead to tapered sidewalls, as indicated by dash line DL1, in some other embodiments.

Although the holes O1 depicted in FIG. 3B are round (or circular) holes when viewed from above, holes with other suitable shapes may also be formed in the ILD layer 120. FIG. 3C illustrates a top view of an alternative embodiment of the holes O1 formed in the ILD layer 120. The holes O1 may be square holes (or rectangular holes) each having four straight sidewalls.

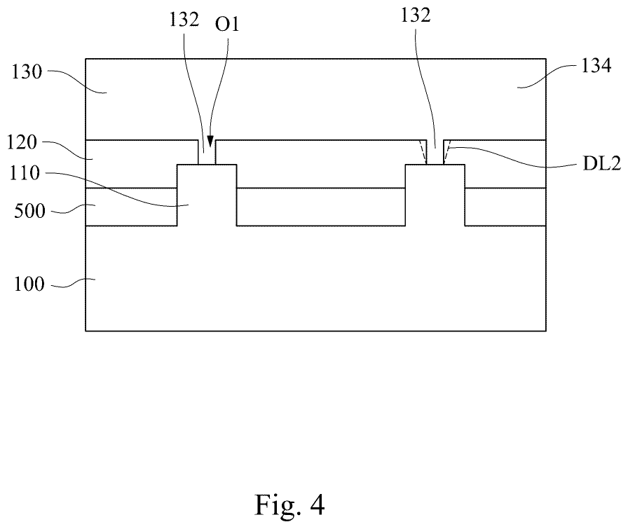

In FIG. 4, a semiconductor layer 130 is formed over the ILD layer 120 using suitable deposition techniques. The deposited semiconductor layer 130 is non-single crystalline, and is amorphous and/or polycrystalline. The semiconductor layer 130 includes silicon (Si), germanium (Ge), silicon germanium (SiGe), or other semiconductor materials. In some embodiments where the semiconductor layer 130 is silicon, the silicon layer may be deposited by using silicon-containing gases (e.g., SiH₄, Si₂H₆, Si₃H₈) as precursor gases. The silicon layer may be deposited, for example, at a flow rate of the silicon-containing gas in the range from about 1000 standard cubic centimeters per minute (sccm) to about 2000 sccm, at a temperature in a rage from about 350 degrees Centigrade to about 600 degrees Centigrade, at a pressure in a range from about 400 mTorr to about 1 Torr. These process conditions for forming the silicon layer 130 is intended to be illustrative and is not intended to be limiting to embodiments of the present disclosure. Rather, any suitable processes and associated process conditions may be used.

Silicon atoms and/or germanium atoms of the semiconductor layer 130 deposited on the ILD layer 120 tend to form an amorphous solid (i.e., non-crystalline solid) that lacks the long-range order of a crystal, because the dielectric material of the ILD layer 120 is amorphous in nature. At an initial stage, the amorphous semiconductor layer 130 is conformally deposited into the holes O1 in the ILD layer 120 and on a top surface of the ILD layer 120, and the deposition process then continues until the holes O1 in the ILD layer 120 are overfilled with the amorphous semiconductor layer 130.

As a result of the deposition process, the amorphous semiconductor layer 130 includes amorphous semiconductor plugs 132 extending in the holes O1 in the ILD layer 120, and an amorphous semiconductor lateral portion 134 extending along a top surface of the ILD layer 120. Height of the amorphous semiconductor plugs 132 is equal to the depth of the holes O1 in the ILD layer 120, and thus is less than the thickness of the ILD layer 104. Height of the semiconductor pillar 110 is greater than height of the semiconductor plug 132. The semiconductor plug 132 has opposite sidewalls respectively offset from opposite sidewalls of a corresponding semiconductor pillar 110. Thickness of the amorphous semiconductor lateral portion 134 can be less than, greater than, or equal to the height of the amorphous silicon plugs 132. In some embodiments, the thickness of the amorphous semiconductor lateral portion 134 is greater than 0 and less than about 1 μm.

In some embodiments where amorphous semiconductor plugs 132 are formed in circular holes as illustrated in FIG. 3B, the amorphous semiconductor plus 132 each have a circular top-view profile. In some embodiments where amorphous semiconductor plugs 132 are formed in quadrilateral holes (e.g., square holes) as illustrated in FIG. 3C, the amorphous semiconductor plus 132 each have a quadrilateral top-view profile (e.g., square top-view profile). The top-view profiles are merely intended to be illustrative and are not intended to be limiting to embodiments of the present disclosure. Moreover, in some embodiments where the holes O1 in the ILD layer 120 have tapered sidewalls, as indicated by dash line DL1 illustrated in FIG. 3A, the amorphous silicon plugs 132 and the tapered sidewalls of the holes O1 may form tapered interfaces, as indicated by dash line DL2 illustrated in FIG. 4.

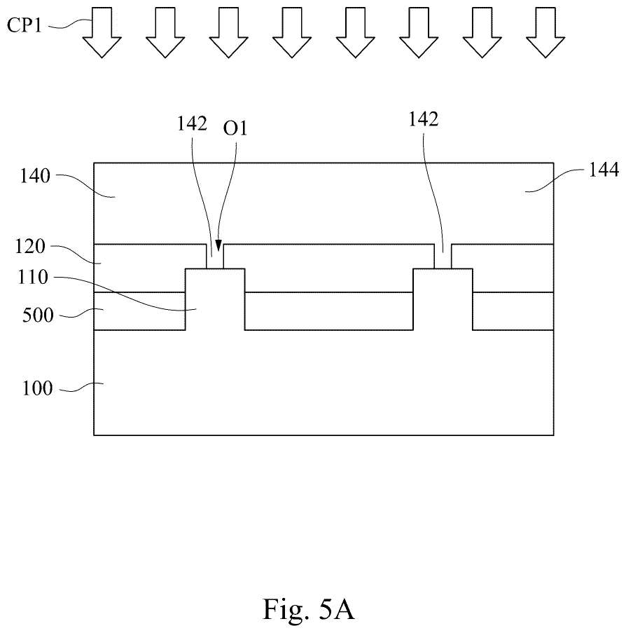

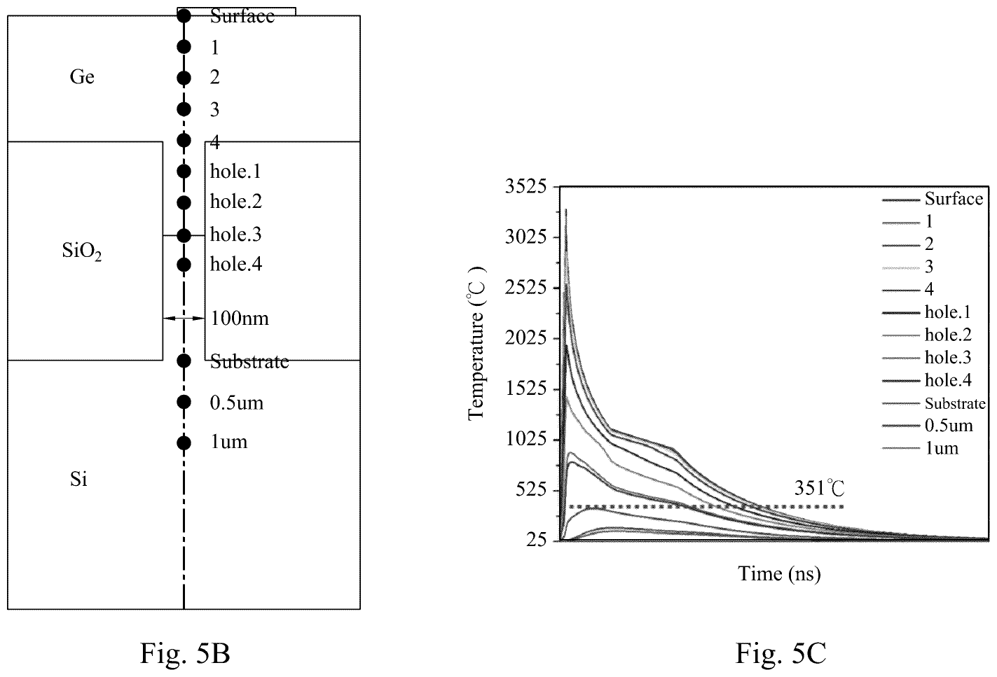

In FIG. 5A, a crystallization process CP1 is performed to convert the amorphous semiconductor layer 130 into a single-crystalline semiconductor layer 140. In some embodiments, crystallization of the amorphous semiconductor layer 130 can be performed using, for example, a laser anneal, a rapid thermal anneal (RTA), a millisecond anneal (mSA), the like or combinations thereof, which raises temperature to a peak temperature higher than deposition temperature of the amorphous semiconductor layer 130. In greater detail, the amorphous semiconductor layer 130 can heated to a peak temperature higher than a melting point of the amorphous semiconductor layer 130 to melt the amorphous semiconductor layer 130 into a molten state, and then the molten amorphous semiconductor will be crystallized upon cooling. Because crystallization of the molten amorphous semiconductor takes place using the underlying single-crystalline semiconductor pillars 110 as seeds, the resultant crystallized semiconductor layer 140 will be single-crystalline instead of polycrystalline, and thus can be referred to as a single-crystalline semiconductor layer 140.

Example crystallization process CP1 of the amorphous semiconductor layer 130 is performed by the laser anneal. The laser may be pulsed laser or a continuous wave laser that is directed toward a top surface of the amorphous semiconductor layer 130. Because the amorphous semiconductor layer 130 is raised above the lower-level circuit structure 500 by significantly tall semiconductor pillars 110, the amorphous semiconductor layer 130 can be spaced apart from the lower-level circuit structure 500 by a distance that is long enough to create a significant temperature difference between the amorphous semiconductor layer 130 and the lower-level circuit structure 500 during the laser anneal, which in turn allows for melting the amorphous semiconductor layer 130 while not melting materials in the lower-level circuit structure 500 (e.g., semiconductor materials of FinFETs 504 as illustrated in FIG. 1B). As a result, the lower-level circuit structure 500 will not be damaged by the peak temperature of the laser anneal.

FIGS. 5B and 5C illustrate an example experiment result of laser anneal. In FIG. 5B, the laser anneal is performed on a sample, which includes a silicon substrate of about 500 μm, a silicon pillar protruding from the silicon substrate and having a height greater than about 100 nm, a silicon oxide layer over the silicon substrate and having a thickness of about 500 nm, and a germanium layer formed over the silicon oxide layer and having a thickness of about 200 nm, and a germanium plug extending in a hole in the silicon oxide layer. FIG. 5C illustrates temperature curves of various vertical positions of the sample after initiating the laser anneal, wherein temperature is shown on the vertical axis of FIG. 5C, and time after initiating laser anneal is shown on the horizontal axis of FIG. 5C. As illustrated in the experiment result of the laser anneal, peak temperature at the hole bottom (denoted as “hole.3” in FIGS. 5B and 5C) is higher than 938 degrees Centigrade (i.e., melting point of germanium), and peak temperatures of other positions (denoted as “Surface,” “1,” “2,” “3,” “4,” “hole.1,” “hole.2”) above the hole bottom are all higher than the peak temperature at the hole bottom and thus higher than melting point of germanium. As a result, the laser anneal can completely melt the germanium layer. On the other hand, peak temperature at the bottom of pillar (denoted as “Substrate”) is about 351 degrees Centigrade, which is lower than melting point of silicon and/or germanium. As a result, the laser anneal does not melt fins and source/drain epitaxy structures formed on the substrate surface. Therefore, the experimental result shows that the pillar allows for melting an amorphous semiconductor material above the pillar while not melting materials of transistors in the lower-level circuit structure.

In the crystallization process CP1, various lasers such as a XeCl or other excimer lasers may be used. The laser energy is adjusted to selectively melt amorphous semiconductor layer 130 but not intentionally melt the underlying materials (e.g., materials in the lower-level circuit structure 500). Various energies may be used and may depend upon the melting point of amorphous semiconductor layer 130. For a pulsed laser, the laser energy may further depend on the number and/or frequency of pulses used and the power density and energy are chosen in conjunction with the thickness of the amorphous semiconductor layer 130. The laser power may be in a range from 0 to about 20 Watts. For example, in some embodiments where the amorphous semiconductor layer 130 is silicon, the amorphous silicon layer 130 has a melting point of about 1414 degrees Centigrade and can be melted using a laser emitted using a power from about 6 Watts to about 8 Watts (e.g., about 6.5 Watts). In some other embodiments where the amorphous semiconductor layer 130 is germanium, the amorphous germanium layer 130 has a melting point of about 938 degrees Centigrade and can be melted using a laser emitted using a power from about 5 Watts to about 7 Watts (e.g., about 5.5 Watts).

The wavelength of laser light is chosen to be a wavelength that is absorbable by amorphous semiconductor and in an exemplary embodiment, a wavelength less than 11000 Å may be used. The pulsed laser causes the amorphous semiconductor layer 130 to substantially or completely melt while most or all underlying materials remain a solid material. The amorphous semiconductor layer 130 may be in its completely or substantially molten state from its top surface to its bottommost surface within the ILD layer 120. In some embodiments, because the bottommost surface of the amorphous semiconductor layer 130 is lower than a top surface of the ILD layer 120, at least upper portion of the ILD layer 120 may be unintentionally molten in order to completely melt the amorphous semiconductor layer 130. Moreover, in some embodiments, top portions of the semiconductor pillars 110 may also be unintentionally molten in order to completely melt the amorphous semiconductor layer 130.

Once the laser anneal process stops, the molten amorphous semiconductor cools down and thus starts to crystallize into the single-crystalline layer 140, which includes single-crystalline semiconductor plugs 142 extending in the holes O1 in the ILD layer 120, and a single-crystalline semiconductor film 144 continuously spanning across multiple single-crystalline semiconductor plugs 142. During cooling down, a heat dissipation rate in the ILD layer 120 decreases as a distance from the underlying lower-level circuit structure 500 increases, because the lower-level circuit structure 500 include multiple layers of metal lines and vias that dissipate heat at a faster rate than ambient gases. Therefore, bottoms of the holes O1 in the ILD layer 120 have a faster heat dissipation rate than a top surface of the ILD 120 during cooling down. The heat dissipation rate difference thus results in a lower temperature at bottoms of the holes O1 in the ILD layer 120 than at the top surface of the ILD layer 120, which in turn initiates nucleation of single-crystalline semiconductor material almost only at the bottoms of the holes O1, rather than initiating nucleation uniformly across the ILD layer 120. In some embodiments, the molten amorphous semiconductor can be reheated before spontaneous nucleation on the ILD layer 120 begins, which in turn can aid in initiating nucleation at the bottoms of holes O1 in the ILD layer 120, because the spontaneous nucleation above the top surface of the ILD layer 120 can be suppressed by the reheating. Because the nucleation of semiconductor material begins from the bottom of holes O1, the single-crystalline semiconductor pillars 110 provide nucleation cites so that after cooling down the resultant semiconductor material becomes single-crystalline. As a result, the semiconductor plugs 142 have no grain boundary, and the semiconductor film 144 has no grain boundary as well.

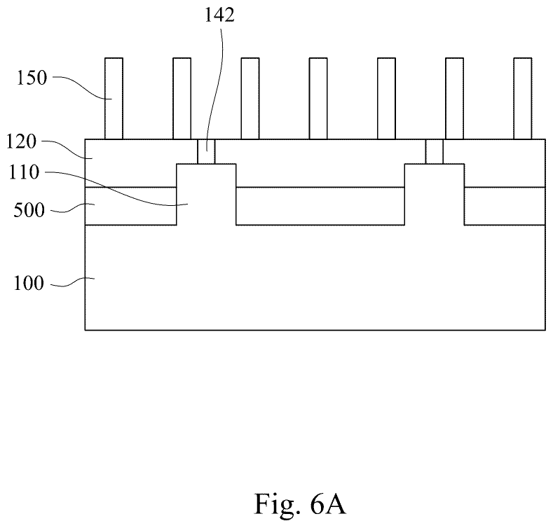

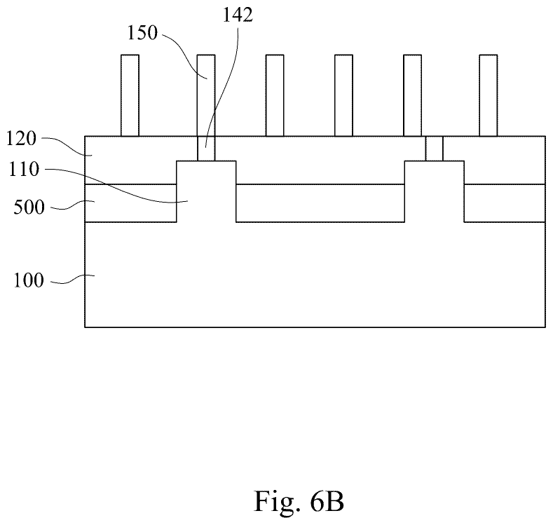

In FIG. 6A, a plurality of single-crystalline semiconductor fins 150 are formed on the ILD layer 120 by patterning the single-crystalline semiconductor film 144 by using suitable photolithography and etching techniques. For example, a photoresist (not shown) may be formed over the single-crystalline semiconductor layer 140 using a spin-on coating process, followed by patterning the photoresist to forming a plurality of holes using suitable photolithography techniques, and then the single-crystalline layer 140 is etched using the patterned photoresist as an etch mask until the ILD layer 120 is exposed, thus resulting in single-crystalline semiconductor fins 150 protruding above the top surface of the ILD layer 120. In the illustrated embodiment of FIG. 6A, the single-crystalline semiconductor plugs 142 are offset from the single-crystalline semiconductor fins 150. However, in some other embodiments, the single-crystalline semiconductor plugs 142 may overlap with the single-crystalline semiconductor fins 150, as illustrated in an alternative embodiment as shown in FIG. 6B. Because the fins 150 are formed above the lower-level circuit structure 500, these fins 150 can be interchangeably referred to as upper-level fins 150 that are disposed above the fins in the lower-level circuit structure 500.

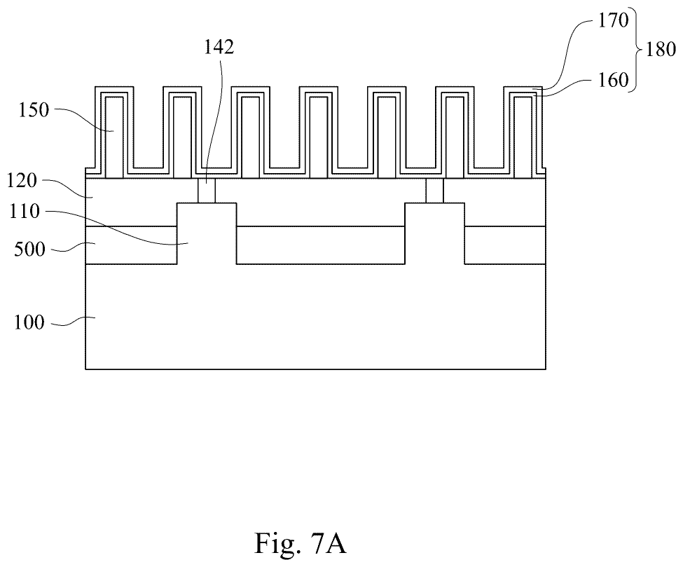

In FIG. 7A and FIG. 7B, a gate dielectric layer 160 is formed over the upper-level fins 150 by using suitable deposition techniques, such as CVD, plasma-enhanced CVD (PECVD), atomic layer deposition (ALD), plasma-enhanced ALD (PEALD) or the like, or by thermal oxidation of the semiconductor surface, or combinations thereof. In some embodiments, gate dielectric layer 160 includes, for example, a high-k dielectric material such as oxides and/or silicates of metals (e.g., oxides and/or silicates of Hf, Al, Zr, La, Mg, Ba, Ti, and other metals), silicon nitride, silicon oxide, and the like, or combinations thereof, or multilayers thereof.

A gate metal layer 170 is formed over the gate dielectric layer 160 by using any suitable method, e.g., CVD, PECVD, physical vapor deposition (PVD), ALD, PEALD, electrochemical plating (ECP), electroless plating and/or the like. In some embodiments, the gate metal layer 170 may be a multilayered metal gate stack comprising a barrier layer, a work function layer, and a top metal layer formed successively on top of gate dielectric layer 160. Example materials for a barrier layer include TiN, TaN, Ti, Ta, or the like, or a multilayered combination thereof. A work function layer may include TiN, TaN, Ru, Mo, Al, for a p-type FET, and Ti, Ag, TaAl, TaAIC, TiAIN, TaC, TaCN, TaSiN, Mn, Zr, for an n-type FET. Other suitable work function materials, or combinations, or multilayers thereof may be used. The top metal layer may comprise metals such as Cu, Al, W, Co, Ru, or the like, or combinations thereof, or multi-layers thereof.

Once deposition of the gate metal layer 170 and the gate dielectric layer 160 is completed, they will be patterned to form a high-k, metal gate (HKMG) gate structure 180 extending across channel regions of the upper-level fins 150, while leaving other regions of the upper-level fins 150 exposed, as illustrated in the perspective view of FIG. 7B.

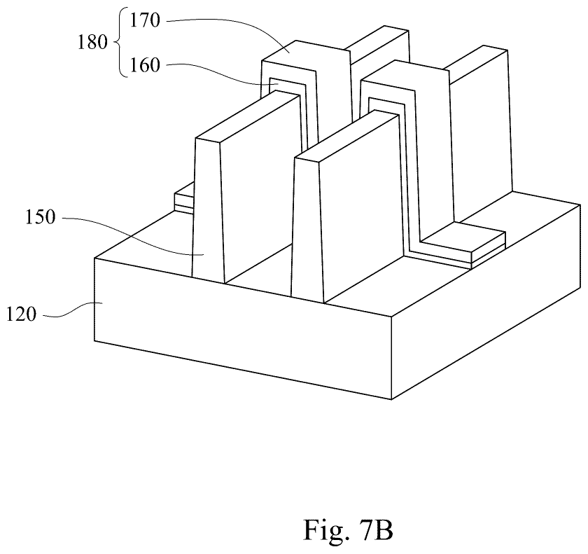

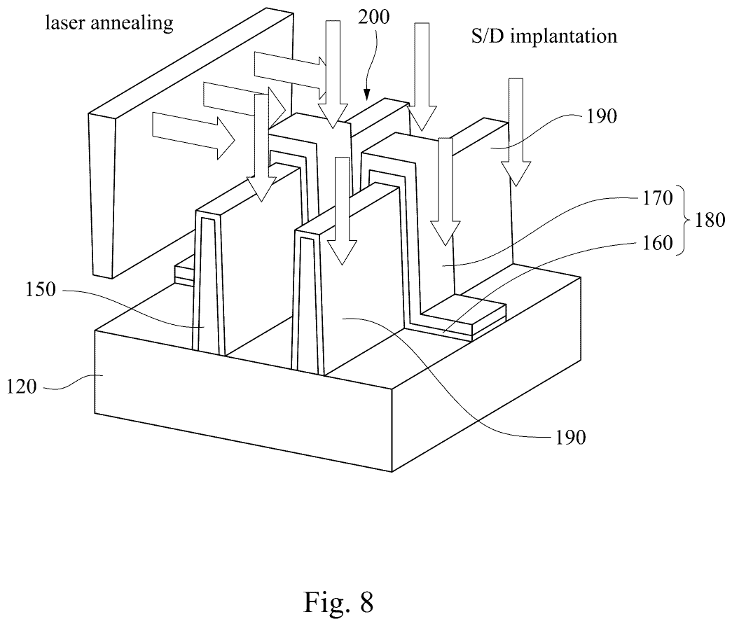

In FIG. 8, a source/drain implantation process is performed to implant n-type or p-type dopants (e.g., As, P, B, In, or the like) on the exposed regions of the upper-level fins 150, and then an anneal is performed on the implanted regions of the upper-level fins 150 to activate the implanted dopants in each implanted regions, thus forming source/drain regions 190 on opposite sides of the HKMG gate structure 180. In some embodiments, activation of the implanted dopants can be performed using, for example, a laser anneal, a rapid thermal anneal (RTA), a millisecond anneal (mSA), the like or combinations thereof. For example, a CO₂ laser may be used to activate the implanted dopants.

The upper-level fins 150, the source/drain regions 190 in the upper-level fins 150, and the gate structure 180 can form upper-level FinFETs 200 on the ILD layer 120. In the illustrated embodiments, the transistors 200 are FinFETs. In some other embodiments, the transistors 200 are planar FETs, gate-all-around (GAA) FETs, nanosheet FETs, nanowire FETs, or other suitable FETs.

In the illustrated embodiment, the upper-level FinFETs 200 are formed without forming additional STI regions above the ILD layer 120. This is because the upper-level fins 150 are formed on the ILD layer 120 and thus can be insulated from each other by the ILD layer 120 without the need of additional STI regions. However, the STI-free fins 150 are intended to be illustrative and not intended to be limiting to embodiments of the present disclosure. In some other embodiments, additional STI regions may be formed around the fins 150 before forming the gate structure 180, thus improving insulation between the fins 150.

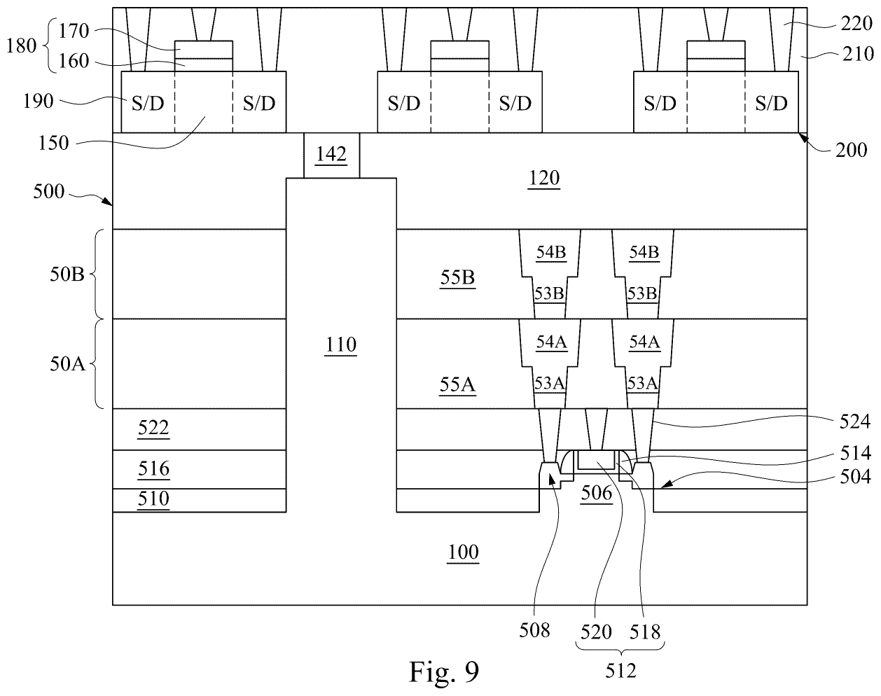

In FIG. 9, an ILD layer 210 is formed over the upper-level FinFETs 200. The ILD layer 210 may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The dielectric materials used to form the first ILD layer 516 and the second ILD layer 522 may be deposited using any suitable method, such as CVD, physical vapor deposition (PVD), ALD, PEALD, PECVD, SACVD, FCVD, spin-on, and/or the like, or a combination thereof. Once the ILD layer 210 is formed, contacts 220 are formed in the ILD layer 210 to land on the gate structures 180 and source/drain regions 190, respectively. In the embodiment illustrated in FIG. 9, some contacts 220 make electrical connections to the source and drain regions 190 of upper-level FinFETs 200 and can be referred to as upper-level source/drain contacts, some contacts 220 make electrical connections to gate structures 180 of upper-level FinFETs 200 and can be referred to as gate contacts. The contacts 220 may be formed using similar processes and materials as discussed previously with respect to the lower-level contacts 524. After forming the contacts 220, another multilevel interconnect structure is formed over the contacts 220 using similar processes and materials as discussed previously with respect to the multilevel interconnect structure 50A and 50B.

The upper-level transistors 200 above the interconnect structure 50A, 50B and the transistors 504 below the interconnect structure 50A, 50B can form an integrated circuit (IC). Because the IC includes transistors at different levels (e.g., transistors 200 at a higher level than transistors 504), it can be referred to as a three dimensional (3D) IC structure.

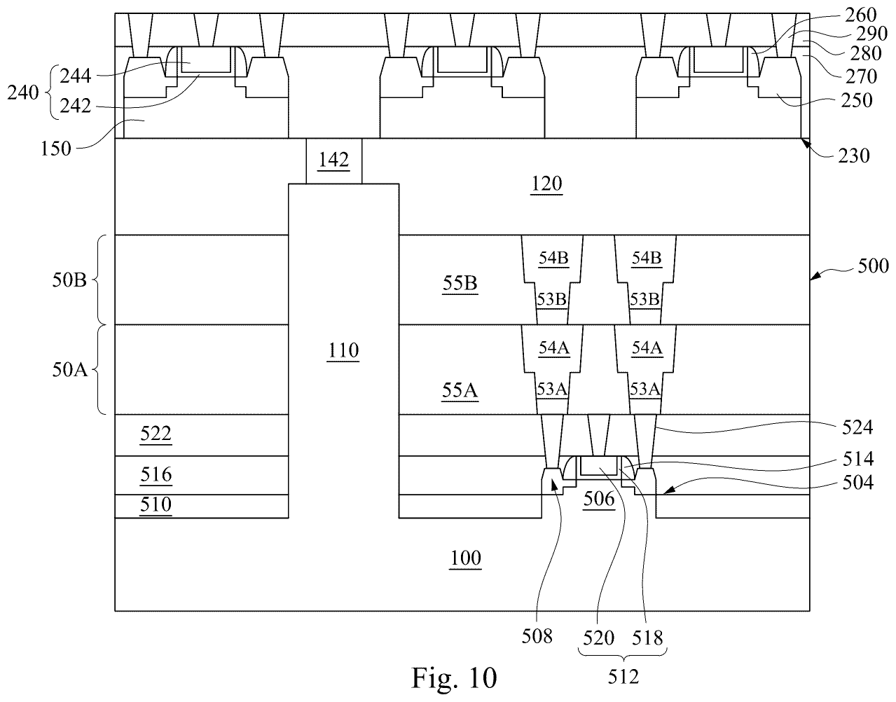

FIG. 10 illustrates an exemplary cross-sectional view of a 3D IC according to some other embodiments of the present disclosure. FIG. 10 shows substantially the same structure as FIG. 9, except that the 3D IC structure includes upper-level FinFETs 230 formed using a different process than the upper-level FinFETs 200 of FIG. 9. The upper-level FinFETs 230 are formed using a gate-last process. In greater detail, a sacrificial dummy gate structure (not shown) is formed after forming the upper-level fins 150. The dummy gate structure may comprise a dummy gate dielectric, a dummy gate electrode, and a hard mask. First a dummy gate dielectric material (e.g., silicon oxide, silicon nitride, or the like) may be deposited. Next a dummy gate material (e.g., amorphous silicon, polycrystalline silicon, or the like) may be deposited over the dummy gate dielectric. A hard mask layer (e.g., silicon nitride, silicon carbide, or the like) may be formed over the dummy gate material. The dummy gate structure is then formed by patterning the hard mask and transferring that pattern to the dummy gate dielectric and dummy gate material using suitable photolithography and etching techniques. The dummy gate structure may extend along multiple sides of the upper-level fins 150. As described in greater detail below, the dummy gate structure may be replaced by the HKMG gate structure 240 as illustrated in FIG. 10. The materials used to form the dummy gate structure and hard mask may be deposited using any suitable method such as CVD, plasma-enhanced CVD (PECVD), atomic layer deposition (ALD), plasma-enhanced ALD (PEALD) or the like, or by thermal oxidation of the semiconductor surface, or combinations thereof.

Source/drain regions 250 and spacers 260 of upper-level FinFETs 230, illustrated in FIG. 10, are formed, for example, self-aligned to the dummy gate structures. Spacers 260 may be formed by deposition and anisotropic etch of a spacer dielectric layer performed after the dummy gate patterning is complete. The spacer dielectric layer may include one or more dielectrics, such as silicon oxide, silicon nitride, silicon oxynitride, silicon carbide, silicon carbonitride, the like, or a combination thereof. The anisotropic etch process removes the spacer dielectric layer from over the top of the dummy gate structures leaving the spacers 260 along the sidewalls of the dummy gate structures.

Source/drain regions 250 are semiconductor regions in direct contact with the upper-level fin 150. In some embodiments, the source/drain regions 250 may comprise heavily-doped regions and relatively lightly-doped drain extensions, or LDD regions. Generally, the heavily-doped regions are spaced away from the dummy gate structures using the spacers 260, whereas the LDD regions may be formed prior to forming spacers 260, and, hence, extend under the spacers 260 and, in some embodiments, extend further into a portion of the upper-level fin 150 below the dummy gate structure. The LDD regions may be formed, for example, by implanting dopants (e.g., As, P, B, In, or the like) using an ion implantation process.

In some embodiments, the source and drain regions 250 may comprise an epitaxially grown region. For example, after forming the LDD regions, the spacers 260 may be formed and, subsequently, the heavily-doped source and drain regions may be formed self-aligned to the spacers 260 by first etching the upper-level fins 150 to form recesses, and then depositing a crystalline semiconductor material in the recess by a selective epitaxial growth (SEG) process that may fill the recess and, typically, extend beyond the original surface of the fin to form a raised source-drain structure, as illustrated in FIG. 10. The crystalline semiconductor material may be elemental (e.g., Si, or Ge, or the like), or an alloy (e.g., Si₁₋ₓCₓ, or Si₁₋ₓGeₓ, or the like). The SEG process may use any suitable epitaxial growth method, such as e.g., vapor/solid/liquid phase epitaxy (VPE, SPE, LPE), or metal-organic CVD (MOCVD), or molecular beam epitaxy (MBE), or the like. A high dose (e.g., from about 10¹⁵ cm⁻² to 10¹⁸ cm⁻²) of dopants may be introduced into the heavily-doped source and drain regions 250 either in situ during SEG, or by an ion implantation process performed after the SEG, or by a combination thereof.

An interlayer dielectric (ILD) 270 is deposited over the structure. In some embodiments, a contact etch stop layer (CESL) (not shown) of a suitable dielectric (e.g., silicon nitride, silicon carbide, or the like, or a combination thereof) may be deposited prior to depositing the ILD material. A planarization process (e.g., CMP) may be performed to remove excess ILD material and any remaining hard mask material from over the dummy gates to form a top surface wherein the top surface of the dummy gate material is exposed and may be substantially coplanar with the top surface of the first ILD 270. The HKMG gate structures 240, illustrated in FIG. 10, may then be formed by first removing the dummy gate structures using one or more etching techniques, thereby creating trenches between respective spacers 260. Next, a replacement gate dielectric layer 242 comprising one more dielectrics, followed by a replacement conductive gate layer 244 comprising one or more conductive materials, are deposited to completely fill the recesses. Excess portions of the gate structure layers 242 and 244 may be removed from over the top surface of first ILD 270 using, for example a CMP process. The resulting structure, as illustrated in FIG. 10, may be a substantially coplanar surface comprising an exposed top surface of first ILD 270, spacers 514, and remaining portions of the HKMG gate layers 242 and 244 inlaid between respective spacers 260.

The gate dielectric layer 242 includes, for example, a high-k dielectric material such as oxides and/or silicates of metals (e.g., oxides and/or silicates of Hf, Al, Zr, La, Mg, Ba, Ti, and other metals), silicon nitride, silicon oxide, and the like, or combinations thereof, or multilayers thereof. In some embodiments, the conductive gate layer 244 may be a multilayered metal gate stack comprising a barrier layer, a work function layer, and a gate-fill layer formed successively on top of gate dielectric layer 242. Example materials for a barrier layer include TIN, TaN, Ti, Ta, or the like, or a multilayered combination thereof. A work function layer may include TiN, TaN, Ru, Mo, Al, for a p-type FET, and Ti, Ag, TaAl, TaAIC, TiAIN, TaC, TaCN, TaSiN, Mn, Zr, for an n-type FET. Other suitable work function materials, or combinations, or multilayers thereof may be used. The gate-fill layer which fills the remainder of the recess may comprise metals such as Cu, Al, W, Co, Ru, or the like, or combinations thereof, or multi-layers thereof. The materials used in forming the gate structure may be deposited by any suitable method, e.g., CVD, PECVD, physical vapor deposition (PVD), ALD, PEALD, electrochemical plating (ECP), electroless plating and/or the like.

Another ILD layer 280 may be deposited over the ILD layer 270, as illustrated in FIG. 10. In some embodiments, the insulating materials to form the ILD layers 270 and 280 may comprise silicon oxide, phosphosilicate glass (PSG), borosilicate glass (BSG), boron-doped phosphosilicate glass (BPSG), undoped silicate glass (USG), a low dielectric constant (low-k) dielectric such as, fluorosilicate glass (FSG), silicon oxycarbide (SiOCH), carbon-doped oxide (CDO), flowable oxide, or porous oxides (e.g., xerogels/aerogels), or the like, or a combination thereof. The dielectric materials used to form the ILD layers 270 and 280 may be deposited using any suitable method, such as CVD, physical vapor deposition (PVD), ALD, PEALD, PECVD, SACVD, FCVD, spin-on, and/or the like, or a combination thereof.

Once the ILD layer 280 is formed, contacts 290 are formed in the ILD layers 270, 280 to land on the gate structures 240 and source/drain regions 250, respectively. In the embodiment illustrated in FIG. 10, some contacts 290 make electrical connections to the source and drain regions 250 of upper-level FinFETs 230 and can be referred to as upper-level source/drain contacts, some contacts 290 make electrical connections to gate structures 240 of upper-level FinFETs 230 and can be referred to as gate contacts. The contacts 290 may be formed using similar processes and materials as discussed previously with respect to the lower-level contacts 524. After forming the contacts 290, another multilevel interconnect structure is formed over the contacts 290 using similar processes and materials as discussed previously with respect to the multilevel interconnect structure 50A and 50B.

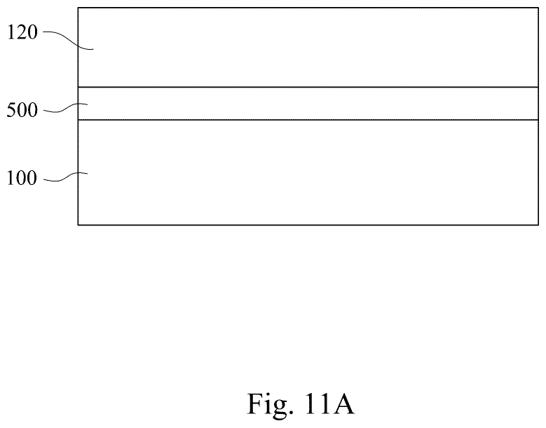

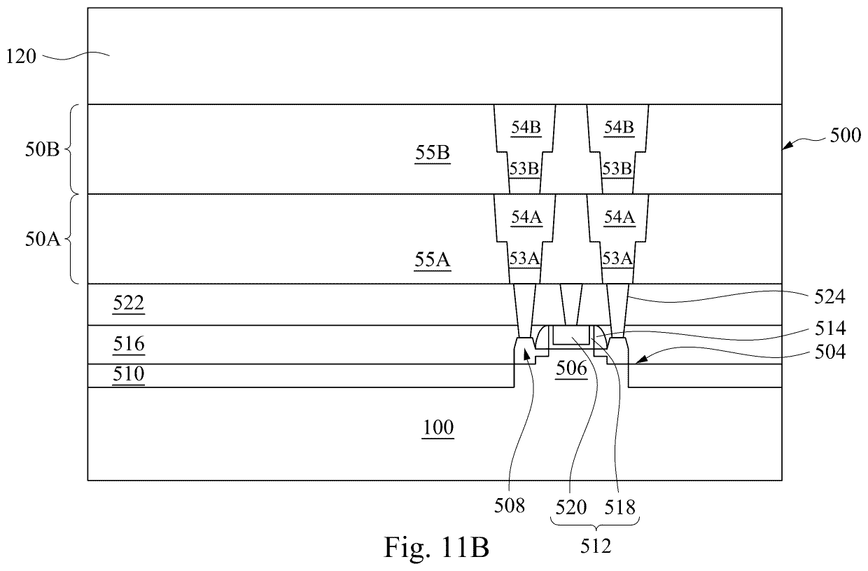

FIGS. 11A-19 illustrate intermediate stages of a method of forming a 3D IC structure in accordance with some embodiments. Although the cross-sectional views shown in FIGS. 11A-19 are described with reference to a method, it will be appreciated that the structures shown in FIGS. 11A-19 are not limited to the method but rather may stand alone separate of the method. Although FIGS. 11A-19 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

FIGS. 11A and 11B are cross-sectional views of an example initial structure comprising a semiconductor substrate 100 and a lower-level circuit structure 500 formed over the semiconductor substrate 100. FIGS. 11A and 11B show substantially the same structure as FIGS. 1A and 1B, except that the semiconductor pillars 110 are omitted. Stated another way, the substrate 100 is merely patterned to form fins 506, and not patterned to form pillars 110.

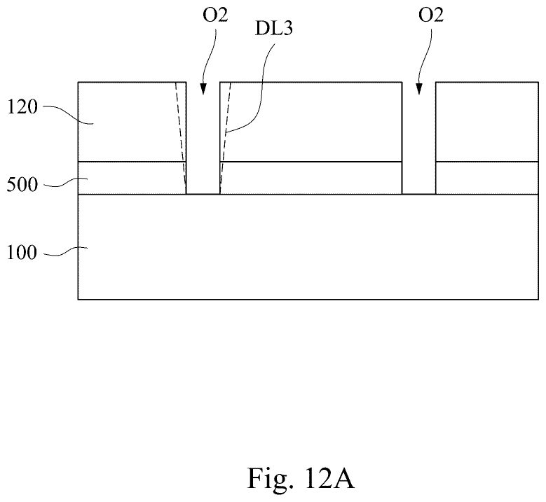

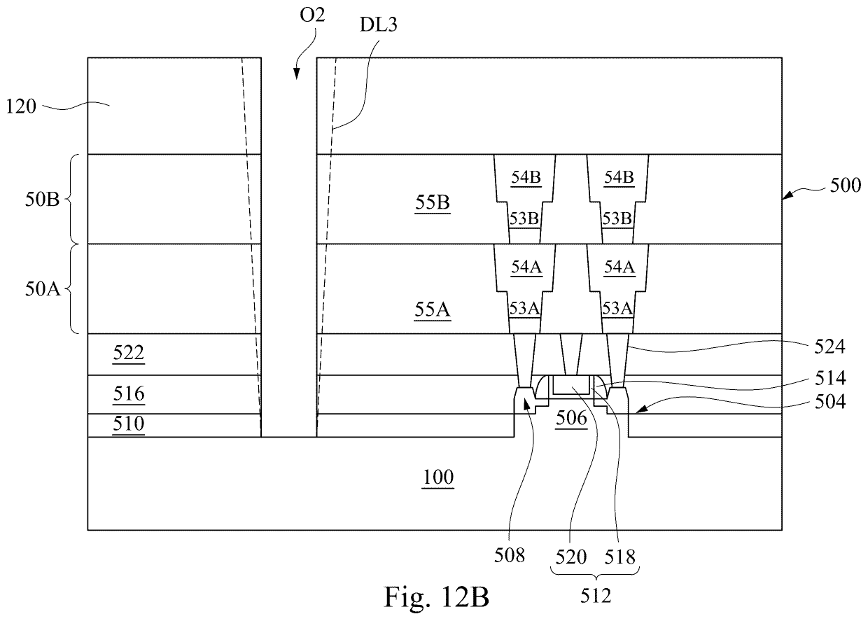

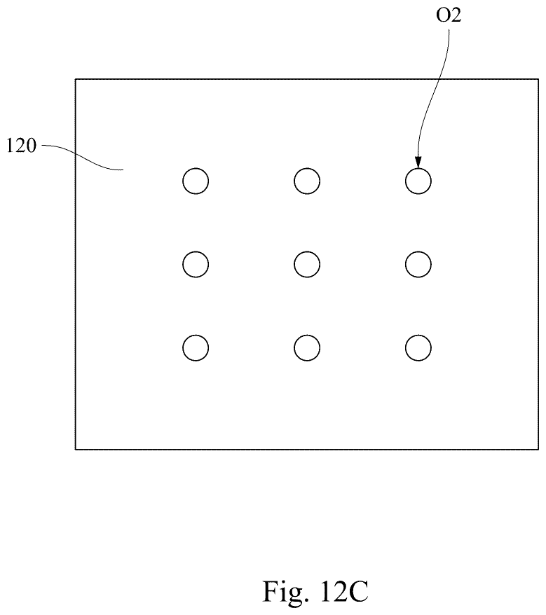

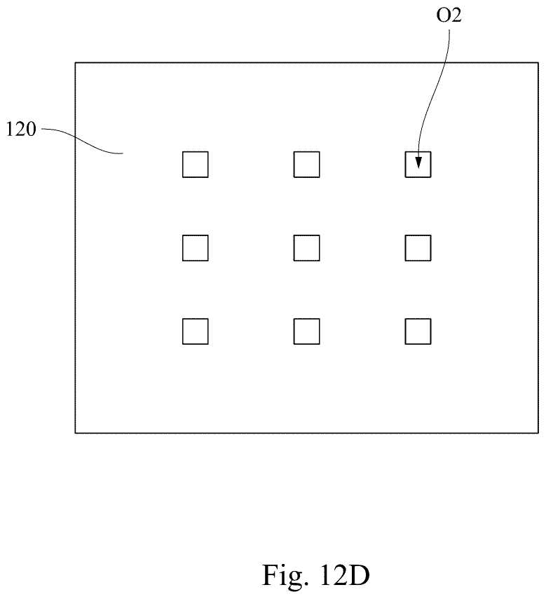

In FIGS. 12A and 12B, holes O2 are etched in the ILD layer 120 and the lower-level circuit structure 500 until the single-crystalline semiconductor substrate 100 is exposed. The holes O2 are arranged equidistantly in rows and columns, as illustrated in the top views of FIGS. 12C and 12D. In some embodiments, the holes O2 each have a vertical dimension (i.e., depth) less than 1 μm and a lateral dimension (e.g., diameter or width) in a range from about 1 nm to about 1 μm.

The ILD layer 120 is patterned using suitable photolithography and etching techniques. For example, a photoresist layer is formed over the ILD layer 120 by using a spin-on coating process, followed by patterning the photoresist layer to expose target regions of the ILD layer 120 using suitable photolithography techniques. For example, photoresist layer is irradiated (exposed) and developed to remove portions of the photoresist layer. In greater detail, a photomask or reticle (not shown) may be placed above the photoresist layer, which may then be exposed to a radiation beam which may be ultraviolet (UV) or an excimer laser such as a Krypton Fluoride (KrF) excimer laser, or an Argon Fluoride (ArF) excimer laser. Exposure of the photoresist material may be performed, for example, using an immersion lithography tool or an extreme ultraviolet light (EUV) tool to increase resolution and decrease the minimum achievable pitch. A bake or cure operation may be performed to harden the exposed photoresist layer, and a developer may be used to remove either the exposed or unexposed portions of the photoresist material depending on whether a positive or negative resist is used. After the patterned photoresist layer is formed, an etching process is performed on the exposed target regions of the ILD layer 120, thus forming holes O2 in the ILD layer 120 and in the lower-level circuit structure 500. Although the holes O2 illustrated in FIGS. 12A and 12B have vertical sidewalls, the etching process may lead to tapered sidewalls, as indicated by dash line DL3, in some other embodiments.

Although the holes O2 depicted in FIG. 12C are round (or circular) holes when viewed from above, holes with other suitable shapes may also be formed in the ILD layer 120. FIG. 12D illustrates a top view of an alternative embodiment of the holes O2 formed in the ILD layer 120. The holes O2 may be square holes (or rectangular holes) each having four straight sidewalls.

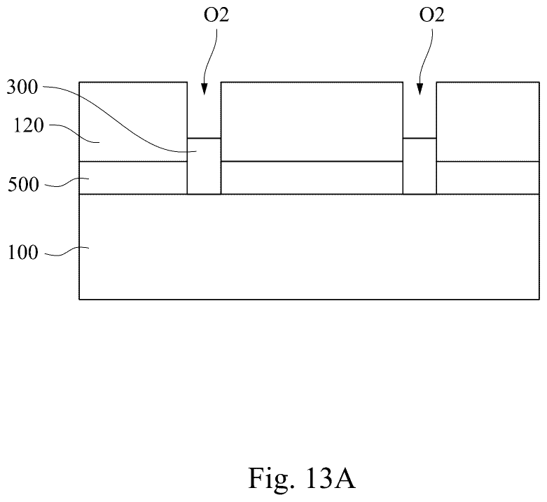

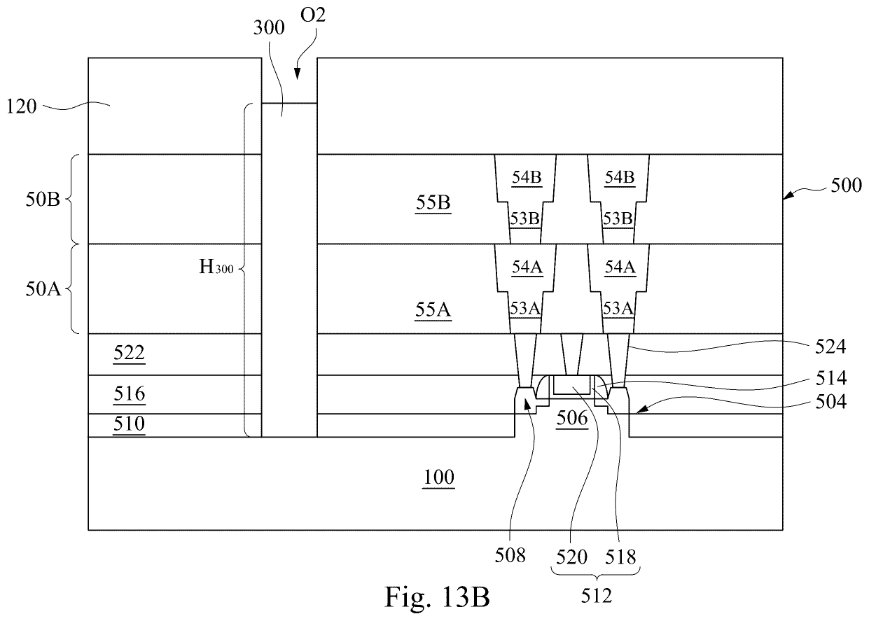

In FIGS. 13A and 13B, single-crystalline semiconductor pillars 300 are formed in the holes O2 in the lower-level circuit structure 500 and the ILD layer 120. The single-crystalline semiconductor pillars 300 are Si, Ge, or SiGe formed using low-temperature epitaxy growth at a temperature not higher than melting point of the semiconductor materials of the lower-level transistor 504. Therefore, epitaxy growth of the single-crystalline semiconductor pillars 300 has no or negligible impact on the lower-level transistor 504. Because the semiconductor pillars 300 are formed using epitaxy growth, they can be interchangeably referred to as epitaxial pillars 300. For example, in some embodiments where the semiconductor pillars 300 include silicon, the silicon pillars 300 can be formed by low-temperature epitaxy using silane (SiH₄), disilane (Si₂H₆), trisilane (Si₃H₈), or other silicon-containing precursors such as high-order silanes. The silicon-containing precursors may also contain chlorine, e.g. SiH₂Cl₂. The epitaxy growth temperature may be an elevated temperature higher than room temperature (about 21° C.). For example, the temperature may be lower than about 500 degrees Centigrade. A low growth temperature minimizes the likelihood of melting the lower-level fins 506 and source/drain regions 508 on the lower-level fins 506.

The low-temperature epitaxy growth continues at least until the epitaxial pillars 300 have top surfaces above the lower-level circuit structure 500, and thus the epitaxial pillars 300 have heights much greater than heights of the semiconductor fins 506. For example, a ratio of a height of epitaxial pillar 300 to a height of semiconductor fin 506 is greater than 5, 6, 7, 8, 9, 10, or more. Such a height difference allows for melting a semiconductor material subsequently formed over the lower-level circuit structure 500, while not melting materials of the lower-level circuit structure 500, e.g., semiconductor materials of the transistors 504. In some embodiments, the epitaxial pillar 300 has a height H₃₀₀ in a range from about 0.1 to about 1 μm. In some embodiments, the semiconductor pillar height H₃₀₀ is greater than 200 nm.

Because the epitaxial pillars 300 are grown to fill lower portions of the holes O2, the epitaxial pillars 300 have top-view profile and cross-sectional profile the same as the top-view profile and the cross-sectional profile of the holes O2. Therefore, the epitaxial pillars 300 may have vertical sidewalls or tapered sidewalls as indicated by dash line DL3 illustrated in FIGS. 12A and 12B, and the epitaxial pillars 300 may have a circular top-view profile as illustrated in FIG. 12C or quadrilateral top-view profile (or square top-view profile) as illustrated in FIG. 12D.

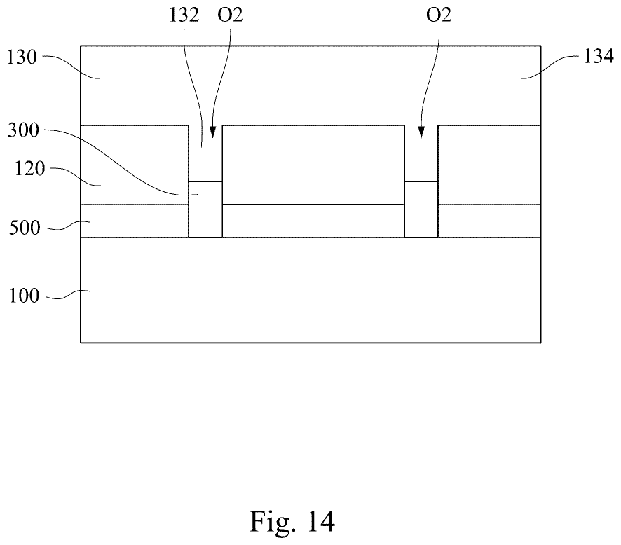

In FIG. 14, a semiconductor layer (e.g., amorphous semiconductor layer) 130 is formed over the ILD layer 120 using suitable deposition techniques. The deposited semiconductor layer 130 is non-single crystalline, and is amorphous and/or polycrystalline. The semiconductor layer 130 includes silicon (Si), germanium (Ge), silicon germanium (SiGe), or other semiconductor materials. Other details about the semiconductor layer 130 are discussed previously with respect to FIG. 4, and thus they are not repeated for the sake of brevity.

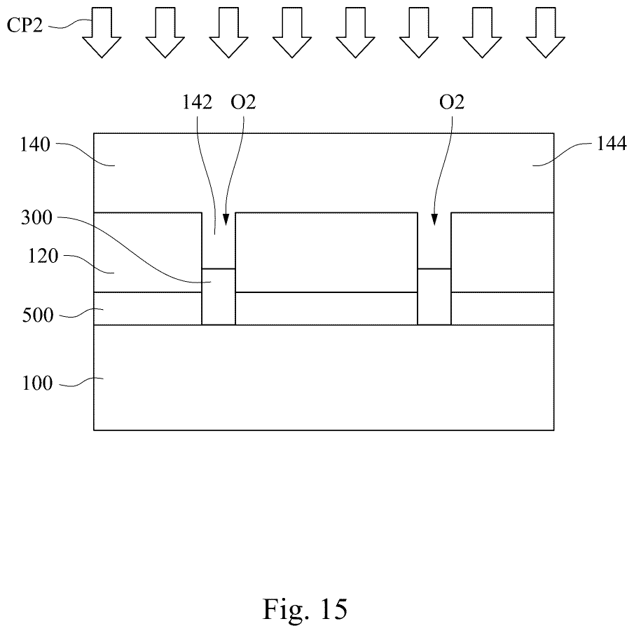

In FIG. 15, a crystallization process CP2 is performed to convert the amorphous semiconductor layer 130 into a single-crystalline semiconductor layer 140. In some embodiments, crystallization of the amorphous semiconductor layer 130 can be performed using, for example, a laser anneal, a rapid thermal anneal (RTA), a millisecond anneal (mSA), the like or combinations thereof, which raises temperature to a peak temperature higher than deposition temperature of the amorphous semiconductor layer 130. In greater detail, the amorphous semiconductor layer 130 can heated to a peak temperature higher than a melting point of the amorphous semiconductor layer 130 to melt the amorphous semiconductor layer 130 into a molten state, and then the molten amorphous semiconductor will be crystallized upon cooling. Because crystallization of the molten amorphous semiconductor takes place using the underlying single-crystalline epitaxial pillars 300 as seeds, the resultant crystallized semiconductor layer 140 will be single-crystalline instead of polycrystalline, and thus can be referred to as a single-crystalline semiconductor layer 140.

Example crystallization process CP2 of the amorphous semiconductor layer 130 is performed by the laser anneal. The laser may be pulsed laser or a continuous wave laser that is directed toward a top surface of the amorphous semiconductor layer 130. Because the amorphous semiconductor layer 130 is raised above the lower-level circuit structure 500 by significantly tall epitaxial pillars 300, the amorphous semiconductor layer 130 can be spaced apart from the lower-level circuit structure 500 by a distance that is long enough to create a significant temperature difference between the amorphous semiconductor layer 130 and the lower-level circuit structure 500 during the laser anneal, which in turn allows for melting the amorphous semiconductor layer 130 while not melting materials in the lower-level circuit structure 500 (e.g., semiconductor materials of FinFETs 504 as illustrated in FIG. 13B). As a result, the lower-level circuit structure 500 will not be damaged by the peak temperature of the laser anneal. In some embodiments, top portions of the epitaxial pillars 300 may also be unintentionally molten in order to completely melt the amorphous semiconductor layer 130.

Once the laser anneal process stops, the molten amorphous semiconductor cools down and starts to crystallize into the single-crystalline layer 140, which includes single-crystalline semiconductor plugs 142 extending in the holes O2 in the ILD layer 120, and a single-crystalline semiconductor film 144 continuously spanning across multiple single-crystalline semiconductor plugs 142. The semiconductor plug 142 has opposite sidewalls respectively aligned with opposite sidewalls of the epitaxial pillar 300. During cooling down, a heat dissipation rate in the ILD layer 120 decreases as a distance from the underlying lower-level circuit structure 500 increases, because the lower-level circuit structure 500 include multiple layers of metal lines and vias that dissipate heat at a faster rate than ambient gases. Therefore, bottoms of the holes O2 in the ILD layer 120 have a faster heat dissipation rate than a top surface of the ILD 120 during cooling down. The heat dissipation rate difference thus results in a lower temperature at bottoms of the holes O2 in the ILD layer 120 than at the top surface of the ILD layer 120, which in turn initiates nucleation of single-crystalline semiconductor material almost only at the bottoms of the holes O2, rather than initiating nucleation uniformly across the ILD layer 120. In some embodiments, the molten amorphous semiconductor can be reheated before spontaneous nucleation on the ILD layer 120 begins, which in turn can aid in initiating nucleation at the bottoms of holes O2 in the ILD layer 120, because the spontaneous nucleation above the top surface of the ILD layer 120 can be suppressed by the reheating. Because the nucleation of semiconductor material begins from the bottom of holes O2, the single-crystalline epitaxial pillars 300 provide nucleation cites such that after cooling down the resultant semiconductor material becomes single-crystalline. As a result, the semiconductor plugs 142 have no grain boundary, and the semiconductor film 144 has no grain boundary as well. Other details about forming the single-crystalline semiconductor layer 140 are discussed previously with respect to FIGS. 5A-5C, and thus they are not repeated for the sake of brevity.

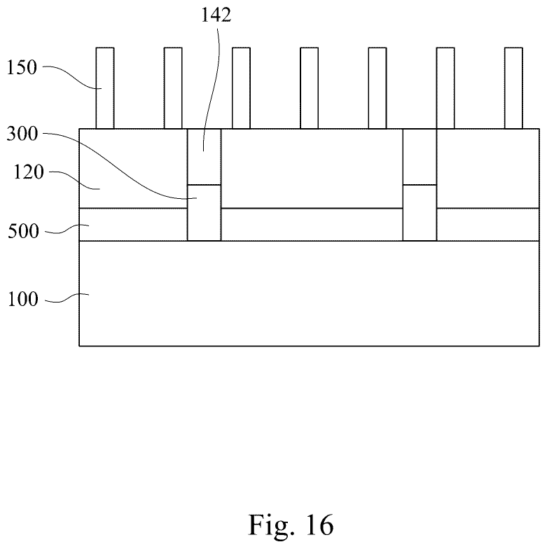

In FIG. 16, a plurality of single-crystalline semiconductor fins 150 are formed on the ILD layer 120 by patterning the single-crystalline semiconductor film 144 by using suitable photolithography and etching techniques. Details about forming the single-crystalline semiconductor fins 150 are discussed previously with respect to FIGS. 6A and 6B, and thus they are not repeated for the sake of brevity.

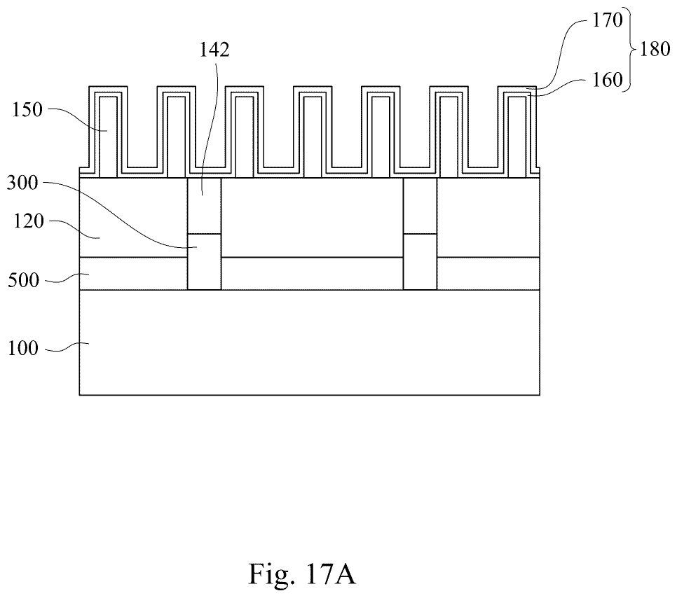

In FIGS. 17A and 17B, a gate dielectric layer 160 and a gate metal layer 170 are deposited in sequence over the upper-level fins 150, followed by patterning the gate dielectric layer 160 and the gate metal layer 170 into a HKMG gate structure 180 extending across channel regions of the upper-level fins 150, while leaving other regions of the upper-level fins 150 exposed, as illustrated in the perspective view of FIG. 17B. Other details about the HKMG gate structure 180 are discussed previously with respect to FIGS. 7A and 7B, and thus they are not repeated for the sake of brevity.

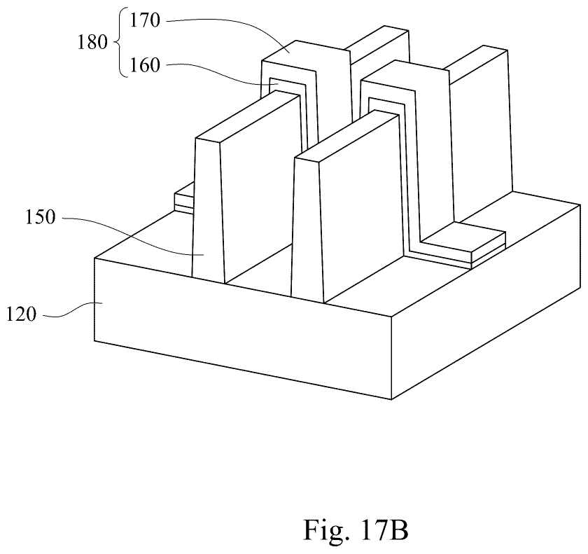

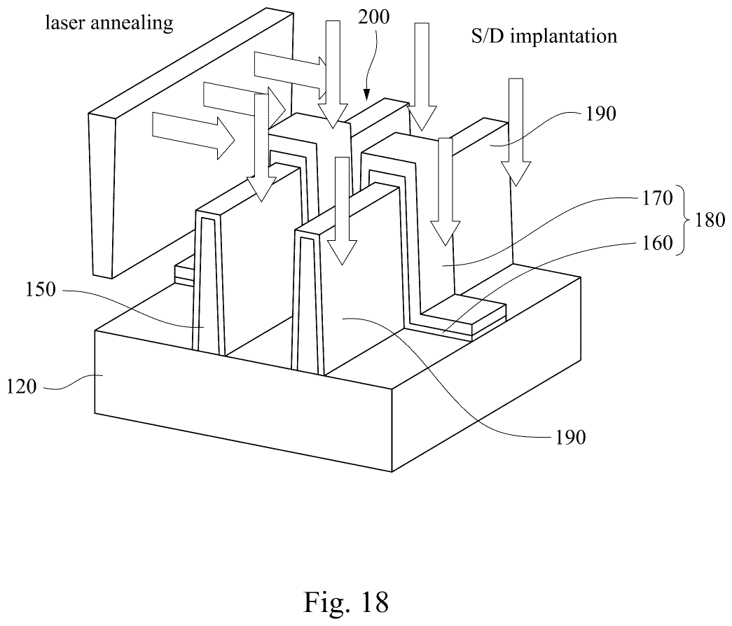

In FIG. 18, a source/drain implantation process is performed to implant n-type or p-type dopants (e.g., As, P, B, In, or the like) on the exposed regions of the upper-level fins 150, and then an anneal is performed on the implanted regions of the upper-level fins 150 to activate the implanted dopants in each implanted regions, thus forming source/drain regions 190 on opposite sides of the HKMG gate structure 180. In some embodiments, activation of the implanted dopants can be performed using, for example, a laser anneal, a rapid thermal anneal (RTA), a millisecond anneal (mSA), the like or combinations thereof. For example, a CO₂ laser may be used to activate the implanted dopants. The upper-level fins 150, the source/drain regions 190 in the upper-level fins 150, and the gate structure 180 can form upper-level FinFETs 200 on the ILD layer 120. In the illustrated embodiments, the transistors 200 are FinFETs. In some other embodiments, the transistors 200 are planar FETs, gate-all-around (GAA) FETs, nanosheet FETs, nanowire FETs, or other suitable FETs.

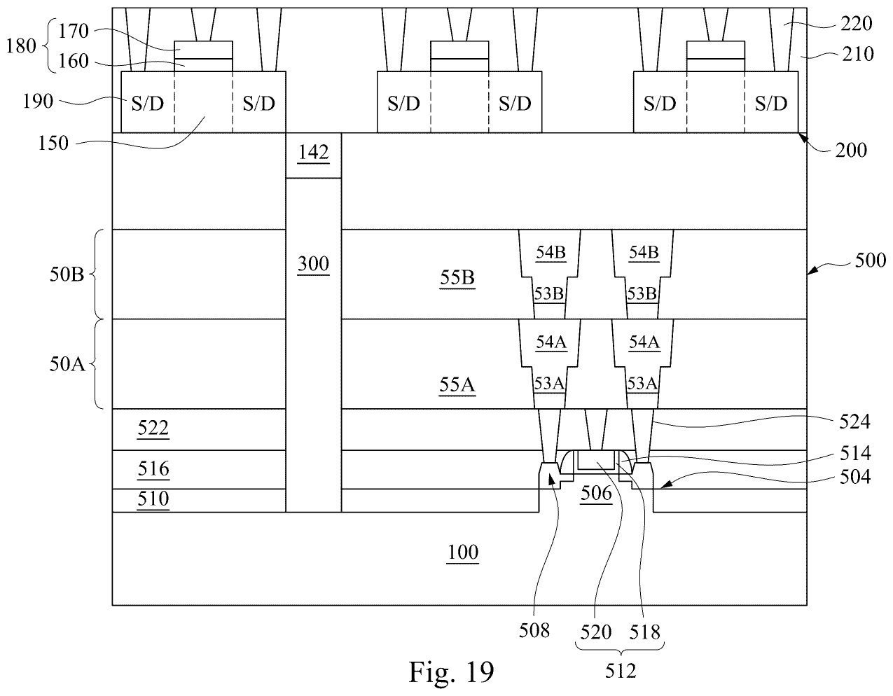

In FIG. 19, an ILD layer 210 is formed over the upper-level FinFETs 200, and contacts 220 are formed in the ILD layer 210 to make electrical connections to the gate structures 180 and source/drain regions 190, respectively. Details about the ILD layer 210 and contacts 220 are discussed previously with respect to FIG. 9, and thus they are not repeated for the sake of brevity.

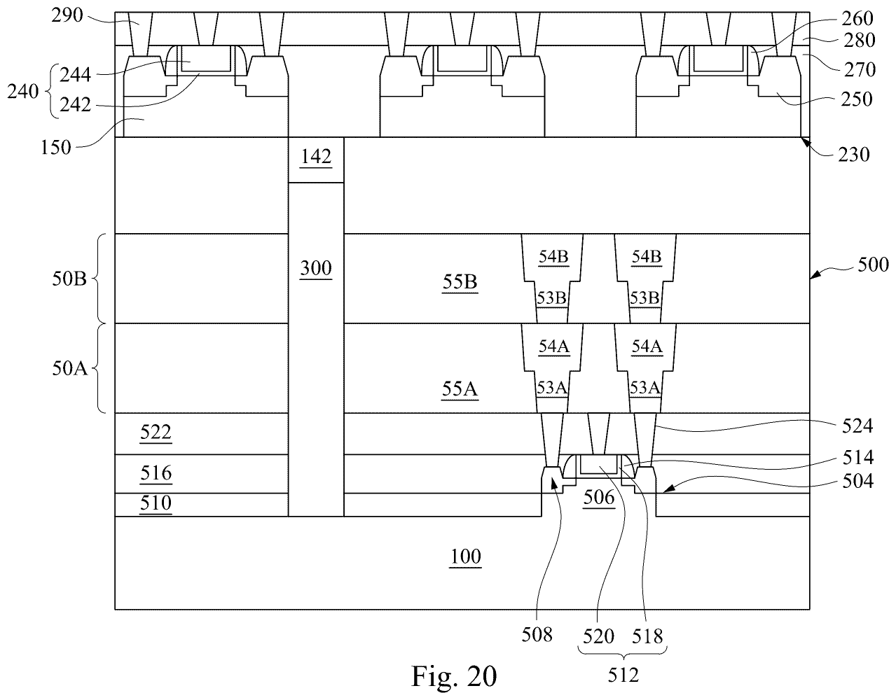

FIG. 20 illustrates an exemplary cross-sectional view of a 3D IC according to some other embodiments of the present disclosure. FIG. 20 shows substantially the same structure as FIG. 19, except that the 3D IC structure includes upper-level FinFETs 230 formed using a different process than the upper-level FinFETs 200 of FIG. 19. The upper-level FinFETs 230 are formed using a gate-last process, and each comprise a replacement HKMG gate structure 240 and epitaxial source/drain regions 250 on opposite sides of the HKMG gate structure 240. Details about the upper-level FinFETs 230 are formed using the gate-last process are discussed previously with respect to FIG. 10, and thus they are not repeated for the sake of brevity. ILD layers 270 and 280 are formed over the upper-level FinFETs 230, and contacts 290 are formed in the ILD layers 270, 280 to make electrical connections to the gate structures 240, and source/drain regions 250, respectively.

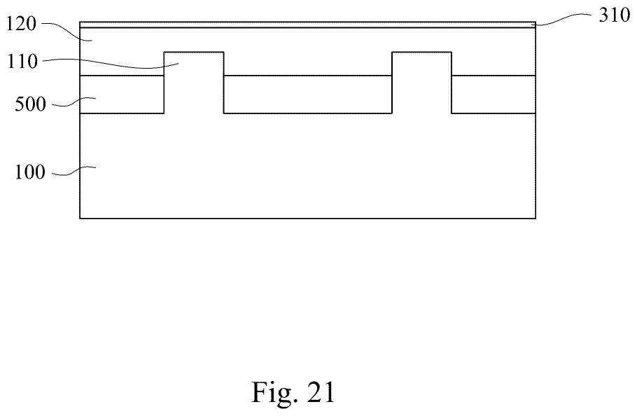

FIGS. 21-28 illustrate intermediate stages of a method of forming a 3D IC structure in accordance with some embodiments. Although the cross-sectional views shown in FIGS. 21-28 are described with reference to a method, it will be appreciated that the structures shown in FIGS. 21-28 are not limited to the method but rather may stand alone separate of the method. Although FIGS. 21-28 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

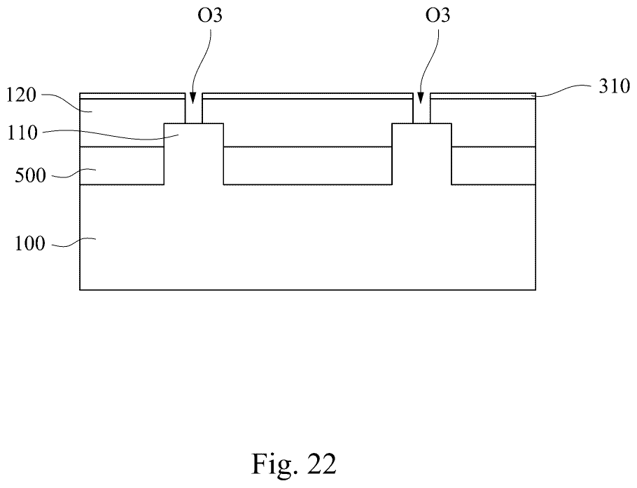

FIG. 21 illustrates a cross-sectional view of a structure after performing CMP on the ILD layer 120, as discussed previously with respect to FIG. 2. After the CMP process is completed, a spontaneous nucleation inhibition layer 310 is on the ILD layer 120, as illustrated in FIG. 20. A material of the spontaneous nucleation inhibition layer 310 is chosen in such a way that spontaneous nucleation of semiconductor material can be suppressed compared with the case where no spontaneous nucleation inhibition layer 310 is formed. The spontaneous nucleation inhibition layer 310 can thus aid in initiating nucleation of single-crystalline semiconductor material at the bottoms of holes O3 in the ILD layer 120 (as shown in FIG. 22), because the spontaneous nucleation of semiconductor material above the top surface of the ILD layer 120 is suppressed. In some embodiments, the spontaneous nucleation inhibition layer 310 includes, for example, silicon nitride (SiNₓ), aluminum oxide (AlO), silicon oxide (SiO₂) or other suitable materials that can suppress spontaneous nucleation of polysilicon. In some embodiments, the spontaneous nucleation inhibition layer 310 is formed using ALD, although other deposition techniques, such as CVD, PVD, PEALD, may be used.

In FIG. 22, holes O3 are etched through the spontaneous nucleation inhibition layer 310 and the ILD layer 120 until the semiconductor pillars 110 are exposed at bottom of the holes O3, respectively. From top view the holes O3 are arranged equidistantly in rows and columns as discussed previously. In some embodiments, the holes O3 each have a vertical dimension (i.e., depth) less than about 1 μm and a lateral dimension (e.g., diameter or width) in a range from about 1 nm to about 1 μm. Other details about forming the holes O3 are discussed previously with respect to FIGS. 3A-3C, and thus they are not repeated for the sake of brevity.

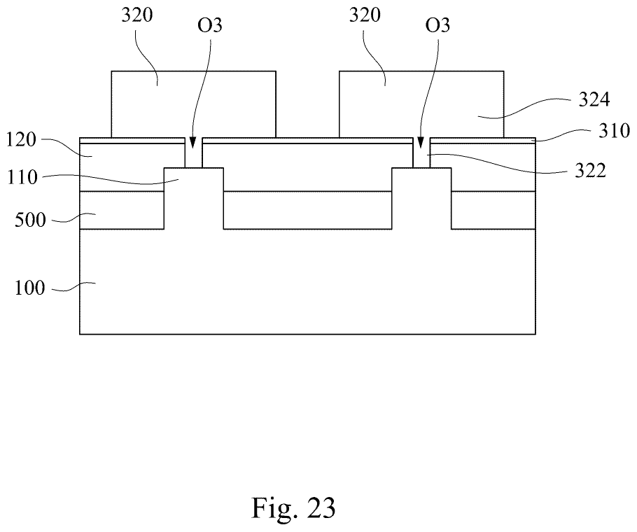

In FIG. 23, a semiconductor layer is deposited over the ILD layer 120 and then patterned into a plurality of semiconductor islands 320 separated from each other. The semiconductor islands 320 are non-single crystalline, and are amorphous and/or polycrystalline. The semiconductor islands 320 include silicon (Si), germanium (Ge), silicon germanium (SiGe), or other semiconductor materials, and can be deposited using suitable deposition techniques same as depositing the semiconductor layer 130 discussed previously with respect to FIG. 4. Silicon atoms and/or germanium atoms of the semiconductor layer deposited on the ILD layer 120 tend to form an amorphous solid (i.e., non-crystalline solid) that lacks the long-range order of a crystal, because the dielectric material of the ILD layer 120 is amorphous in nature. Once the amorphous semiconductor layer is deposited, the amorphous semiconductor layer is patterned using suitable photolithography and etching techniques to form amorphous semiconductor islands 320. In some embodiments, each semiconductor island 320 has a width less than about 5 μm.

The amorphous semiconductor islands 320 respectively overlap corresponding holes O3, and thus the semiconductor islands 320 each comprise an amorphous semiconductor plug 322 extending in the holes O3 in the ILD layer 120, and an amorphous semiconductor lateral portion 324 extending along a top surface of the ILD layer 120. Height of the amorphous semiconductor plugs 322 is equal to the depth of the holes O3 in the ILD layer 120, and thus is less than the thickness of the ILD layer 104. Thickness of the amorphous semiconductor lateral portion 324 can be less than, greater than, or equal to the height of the amorphous silicon plugs 322. In some embodiments, the thickness of the amorphous semiconductor lateral portion 324 is greater than 0 and less than about 1 μm.

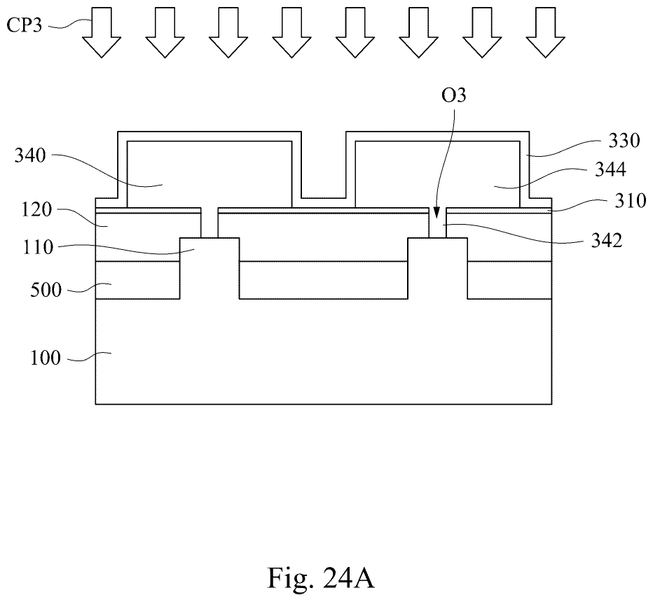

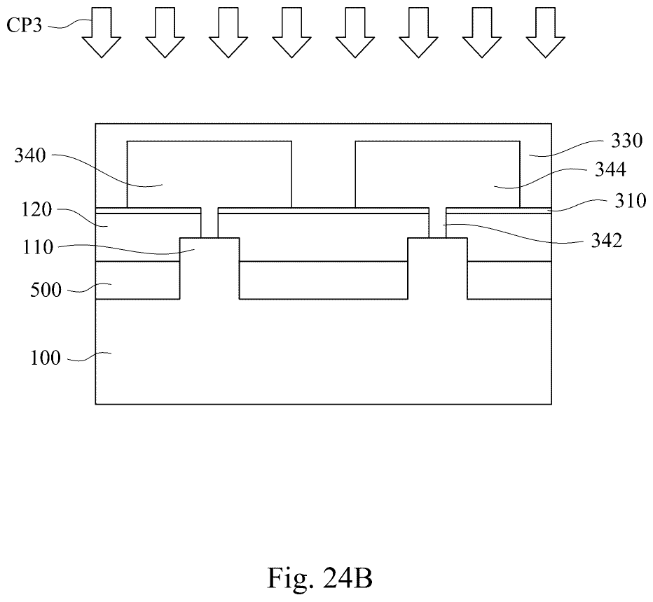

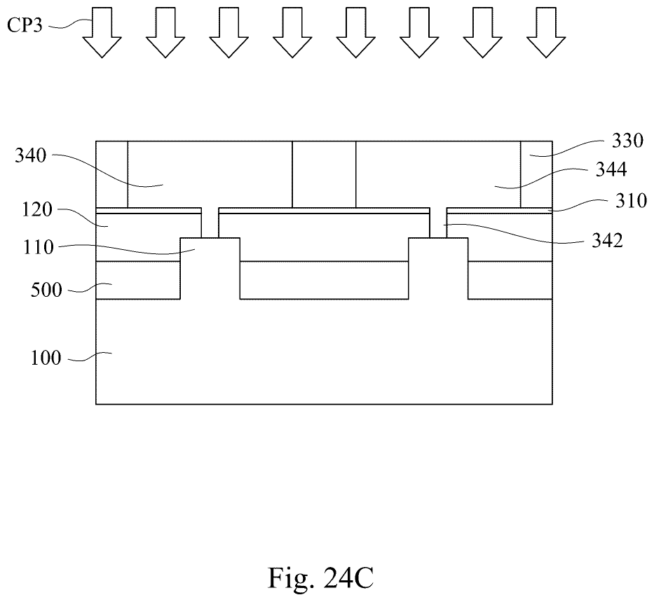

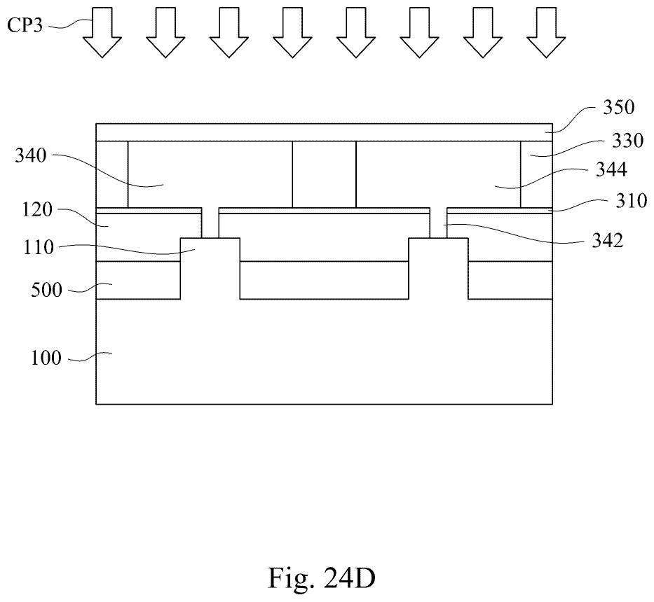

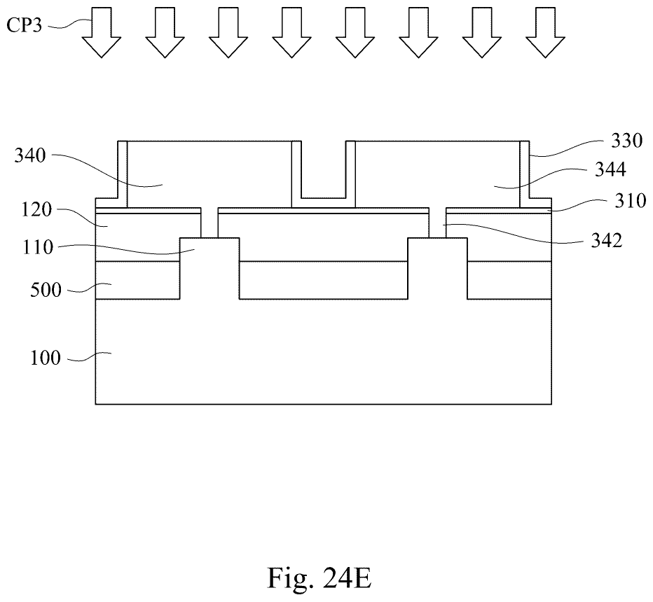

In FIG. 24A, a capping layer 330 is conformally deposited over the amorphous semiconductor islands 320. With the capping layer 330 in place, a crystallization process CP3 is performed to convert the amorphous semiconductor islands 320 into single-crystalline semiconductor islands 340. The capping layer 330 can serve to reduce heat dissipation rate from top surfaces and sidewalls of the amorphous semiconductor islands 320 in the cooling down stage of crystallization process CP3, which in turn improves the heat dissipation rate difference between the hole bottom and surfaces of the amorphous semiconductor islands 320, which in turn aids in initiating nucleation of single-crystalline semiconductor material from the bottoms of the holes O3. The capping layer 330 can also serve to prevent adjacent semiconductor islands from merging during the crystallization process CP3, which in turn reduces the risk of forming grain boundaries and/or crystal defects such as dislocations. In some embodiments the capping layer 330 has a thickness less than about 5 μm.

In some embodiments, crystallization of the amorphous semiconductor islands 320 can be performed using, for example, a laser anneal, a rapid thermal anneal (RTA), a millisecond anneal (mSA), the like or combinations thereof, which raises temperature to a peak temperature higher than deposition temperature of the amorphous semiconductor islands 320. In greater detail, the amorphous semiconductor islands 320 can heated to a peak temperature higher than a melting point of the amorphous semiconductor islands 320 to melt the amorphous semiconductor islands 320 into a molten state, and then the molten amorphous semiconductor islands will be crystallized upon cooling. Because crystallization of the molten amorphous semiconductor islands takes place using the underlying single-crystalline semiconductor pillars 110 as seeds, the resultant crystallized semiconductor islands 340 will be single-crystalline instead of polycrystalline, and thus can be referred to as single-crystalline semiconductor islands 340.

Example crystallization process CP3 of the amorphous semiconductor islands 320 is performed by the laser anneal. The laser may be pulsed laser or a continuous wave laser that is directed toward top surfaces of the amorphous semiconductor islands 320. Because the amorphous semiconductor islands 320 are raised above the lower-level circuit structure 500 by significantly tall semiconductor pillars 110, the amorphous semiconductor islands 320 can be spaced apart from the lower-level circuit structure 500 by a distance that is long enough to create a significant temperature difference between the amorphous semiconductor islands 320 and the lower-level circuit structure 500 during the laser anneal, which in turn allows for melting the amorphous semiconductor islands 320 while not melting materials in the lower-level circuit structure 500 (e.g., semiconductor materials of FinFETs 504). As a result, the lower-level circuit structure 500 will not be damaged by the peak temperature of the laser anneal.

Once the laser anneal process stops, the molten amorphous semiconductor cools down and thus starts to crystallize into single-crystalline semiconductor islands 340. The crystallized semiconductor islands 340 each include a single-crystalline semiconductor plug 342 extending in a corresponding hole O3 in the ILD layer 120, and a single-crystalline semiconductor film 344 continuously spanning across the single-crystalline semiconductor plug 342. During cooling down, a heat dissipation rate in the ILD layer 120 decreases as a distance from the underlying lower-level circuit structure 500 increases, because the lower-level circuit structure 500 include multiple layers of metal lines and vias that dissipate heat at a faster rate than ambient gases, and because heat dissipation from the exposed surfaces of the molten amorphous semiconductor is reduced by the capping layer 330. The heat dissipation rate difference thus results in a lower temperature at bottoms of the holes O3 in the ILD layer 120 than above the top surface of the ILD layer 120, which in turn initiates nucleation of single-crystalline semiconductor material almost only at the bottoms of the holes O3, rather than initiating nucleation uniformly across the ILD layer 120. Moreover, the spontaneous nucleation of single-crystalline semiconductor material above the top surface of the ILD layer 120 can be further suppressed by the spontaneous nucleation inhibition layer 310, and thus the spontaneous nucleation inhibition layer 310 can further aid in initiating nucleation of single-crystalline semiconductor material at the bottoms of the holes O3.

In some embodiments, the molten amorphous semiconductor can be reheated before spontaneous nucleation on the ILD layer 120 begins, which in turn can aid in initiating nucleation at the bottoms of holes O3 in the ILD layer 120, because the spontaneous nucleation above the top surface of the ILD layer 120 can be suppressed by the reheating. Because the nucleation of semiconductor material begins from the bottom of holes O3, the single-crystalline semiconductor pillars 110 provide nucleation cites so that after cooling down the resultant semiconductor material becomes single-crystalline. As a result, the crystallized semiconductor islands 340 have no grain boundary.

FIG. 24B illustrates an alternative embodiment of the capping layer 330. In FIG. 24B, the capping layer 330 is formed to overfill spaces among the amorphous semiconductor islands 320, followed by performing the crystallization process CP3 to convert the amorphous semiconductor islands 320 into the single-crystalline semiconductor islands 340 with the capping layer 330 in place. In some embodiments, the capping layer 330 in FIG. 24B can be formed by CVD, spin-on coating, or other suitable deposition methods.

FIG. 24C illustrates an alternative embodiment of the capping layer 330. In FIG. 24C, the capping layer 330 is formed to fill spaces among the amorphous semiconductor islands 320 while leaving the top surfaces of amorphous semiconductor islands 320 exposed, followed by performing the crystallization process CP3 to convert the amorphous semiconductor islands 320 into the single-crystalline semiconductor islands 340 with the capping layer 330 in place. In some embodiments, the capping layer 330 in FIG. 24C can be formed by overfilling spaces among the amorphous semiconductor islands 320 by a dielectric material using a suitable deposition method, followed by performing a CMP process on the dielectric material to expose top surfaces of the amorphous semiconductor islands 320.

FIG. 24D illustrates an alternative embodiment of the present disclosure. In FIG. 24D, a sidewall capping layer 330 is formed to fill spaces among the amorphous semiconductor islands 320 and a top capping layer 350 is formed over the top surfaces of amorphous semiconductor islands 320, followed by performing the crystallization process CP3 to convert the amorphous semiconductor islands 320 into the single-crystalline semiconductor islands 340 with the sidewall capping layer 330 and top cap layer 350 in place. In some embodiments, the sidewall capping layer 330 in FIG. 24D can be formed by overfilling spaces among the amorphous semiconductor islands 320 by a first dielectric material using a suitable deposition method, followed by performing a CMP process on the first dielectric material to expose top surfaces of the amorphous semiconductor islands 320. The top capping layer 350 in FIG. 24D can be formed by depositing a second dielectric material over the amorphous semiconductor islands 320 and the sidewall capping layer 330, wherein the second dielectric material is different from the first dielectric material. For example, the second dielectric material may have a smaller thermal conductivity than the first dielectric material.

FIG. 24E illustrates an alternative embodiment of the capping layer 330. In FIG. 24E, the capping layer 330 is formed lining sidewalls of the amorphous semiconductor islands 320 while leaving the top surfaces of amorphous semiconductor islands 320 exposed, followed by performing the crystallization process CP3 to convert the amorphous semiconductor islands 320 into the single-crystalline semiconductor islands 340 with the capping layer 330 in place. In some embodiments, the capping layer 330 in FIG. 24E can be formed by depositing a conformal layer over the amorphous semiconductor islands 320 by a dielectric material using a suitable deposition method, followed by performing an angled dry etching process (e.g., plasma etching) on the dielectric material to expose top surfaces of the amorphous semiconductor islands 320, while leaving other portions of the dielectric material remaining on sidewalls of the amorphous semiconductor islands 320 and on top surface of the spontaneous nucleation inhibition layer 310 due to shadowing effect of the angled etching.

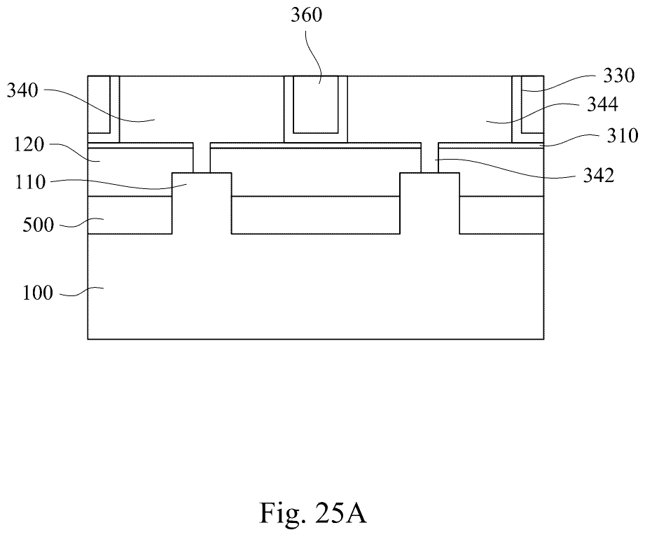

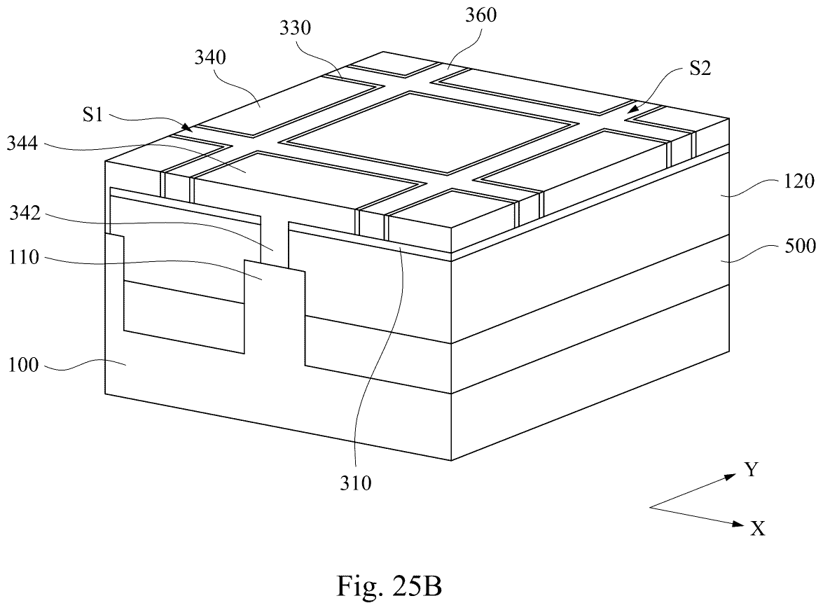

In FIGS. 25A and 25B, a filling dielectric 360 is formed to fill spaces among the single-crystalline semiconductor islands 340. This step may be performed subsequent to the step as shown in FIG. 24A or 24E. In some embodiments, the filling dielectric 360 is formed by first overfilling the spaces among the single-crystalline semiconductor islands 340 with a dielectric material, followed by planarizing the dielectric material by using, e.g., CMP, at least until top surfaces of the single-crystalline semiconductor islands 340 are exposed. As illustrated in the perspective view of FIG. 25B, the semiconductor islands 340 are arranged in rows and columns and have a quadrilateral top-view profile (e.g., rectangular top-view profile or square top-view profile), and the filling dielectric 360 fills X-directional “streets” S1 and Y-directional streets S2 among the semiconductor islands 340. In some embodiments, the streets S1, S2 separating the semiconductor islands 340 have a width from 0 to about 1 μm.

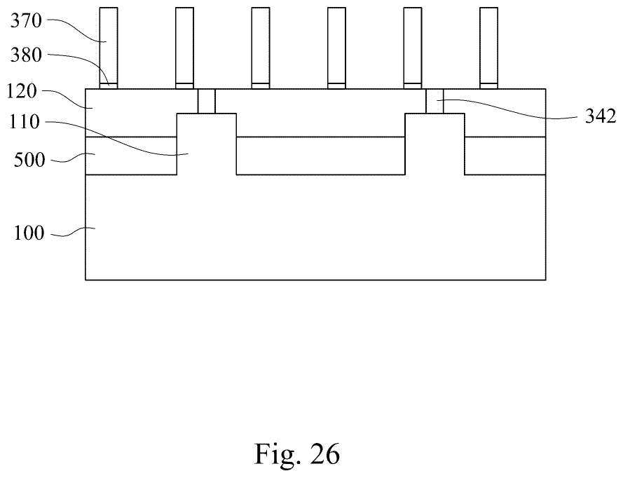

In FIG. 26, a plurality of single-crystalline semiconductor fins 370 are formed on the ILD layer 120 by patterning the single-crystalline semiconductor film 344 by using suitable photolithography and etching techniques. Details about forming the single-crystalline semiconductor fins 370 are discussed previously with respect to FIGS. 6A and 6B, and thus they are not repeated for the sake of brevity. In some embodiments, the spontaneous nucleation inhibition layer 310 is also patterned into separate spontaneous nucleation inhibition strips 380 underling the plurality of single-crystalline semiconductor fins 370. The spontaneous nucleation inhibition strips 380 may have a same top-view pattern as the single-crystalline semiconductor fins 370, because they are formed simultaneously in a same patterning process. Therefore, the spontaneous nucleation inhibition strip 380 has opposite sidewalls aligned with opposite sidewalls of the semiconductor fin 370.

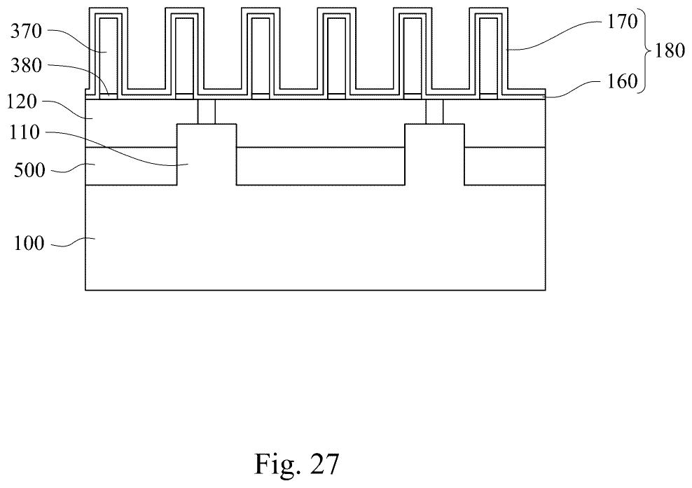

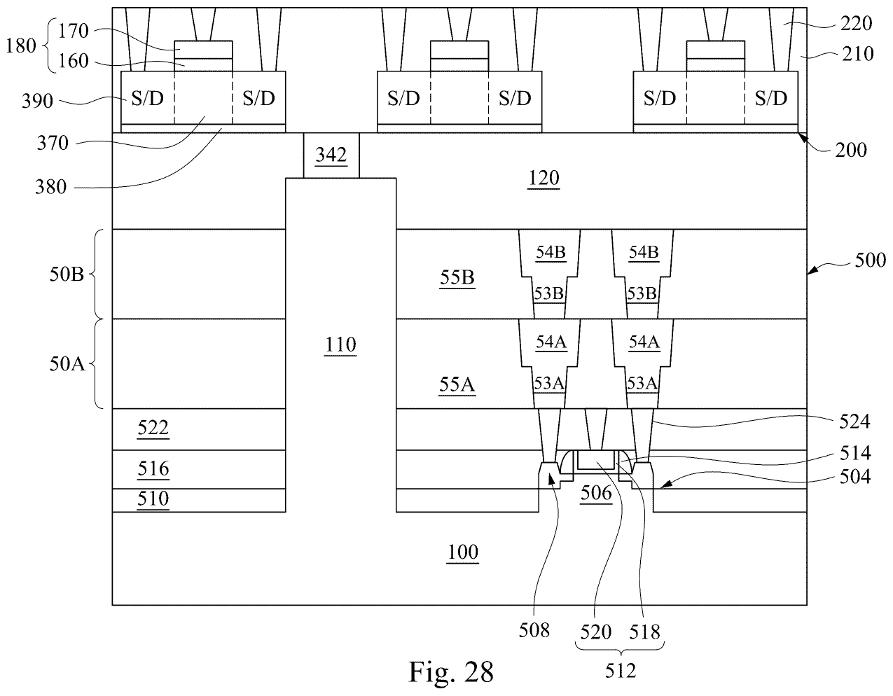

In FIG. 27, a gate dielectric layer 160 and a gate metal layer 170 are deposited in sequence over the upper-level fins 370, followed by patterning the gate dielectric layer 160 and the gate metal layer 170 into a HKMG gate structure 180 extending across channel regions of the upper-level fins 370, while leaving other regions of the upper-level fins 370 exposed. Other details about the HKMG gate structure 180 are discussed previously with respect to FIGS. 7A and 7B, and thus they are not repeated for the sake of brevity. Afterwards, a source/drain implantation process is performed to implant n-type or p-type dopants (e.g., As, P, B, In, or the like) on the exposed regions of the upper-level fins 370, and then an anneal is performed on the implanted regions of the upper-level fins 370 to activate the implanted dopants in each implanted regions, thus forming source/drain regions 390 on opposite sides of the HKMG gate structure 180. The resultant structure is shown in FIG. 28.

The upper-level fins 370, the source/drain regions 390 in the upper-level fins 370, and the gate structure 180 can form upper-level FinFETs 200 on the ILD layer 120. In the illustrated embodiments, the transistors 200 are FinFETs. In some other embodiments, the transistors 200 are planar FETs, gate-all-around (GAA) FETs, nanosheet FETs, nanowire FETs, or other suitable FETs.

In FIG. 28, an ILD layer 210 is formed over the upper-level FinFETs 200, and contacts 220 are formed in the ILD layer 210 to make electrical connections to the gate structures 180 and source/drain regions 390, respectively. Details about the ILD layer 210 and contacts 220 are discussed previously with respect to FIG. 9, and thus they are not repeated for the sake of brevity.

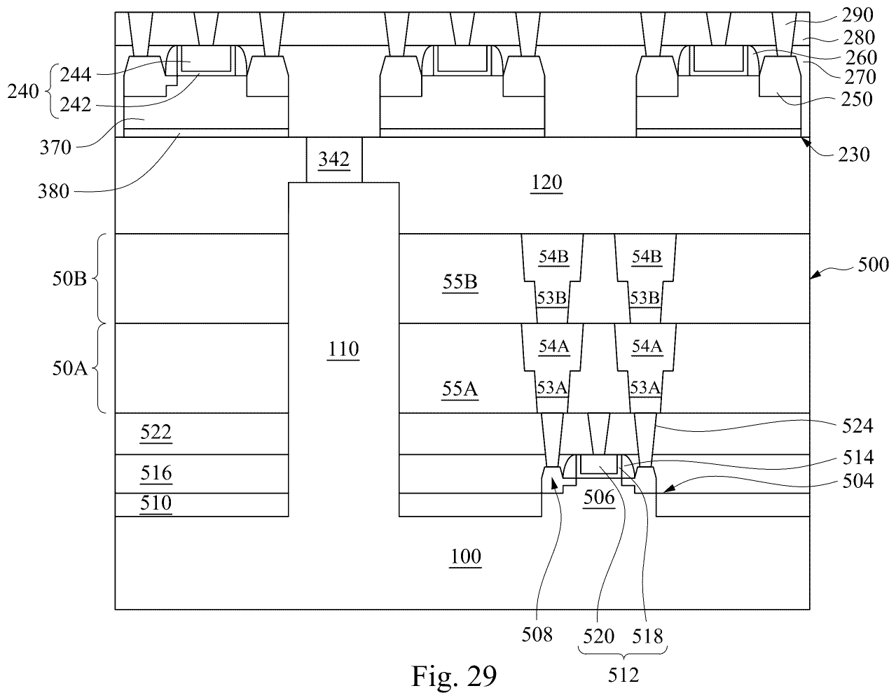

FIG. 29 illustrates an exemplary cross-sectional view of a 3D IC according to some other embodiments of the present disclosure. FIG. 29 shows substantially the same structure as FIG. 28, except that the 3D IC structure includes upper-level FinFETs 230 formed using a different process than the upper-level FinFETs 200 of FIG. 28. The upper-level FinFETs 230 are formed using a gate-last process, and each comprise a replacement HKMG gate structure 240 and epitaxial source/drain regions 250 on opposite sides of the HKMG gate structure 240. Details about the upper-level FinFETs 230 are formed using the gate-last process are discussed previously with respect to FIG. 10, and thus they are not repeated for the sake of brevity. ILD layers 270 and 280 are formed over the upper-level FinFETs 230, and contacts 290 are formed in the ILD layers 270, 280 to make electrical connections to the gate structures 240, and source/drain regions 250, respectively.

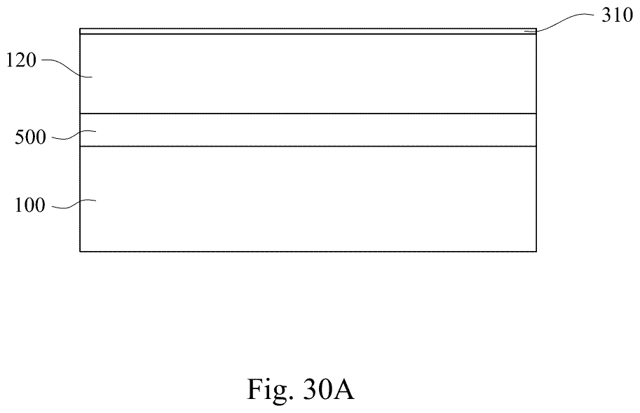

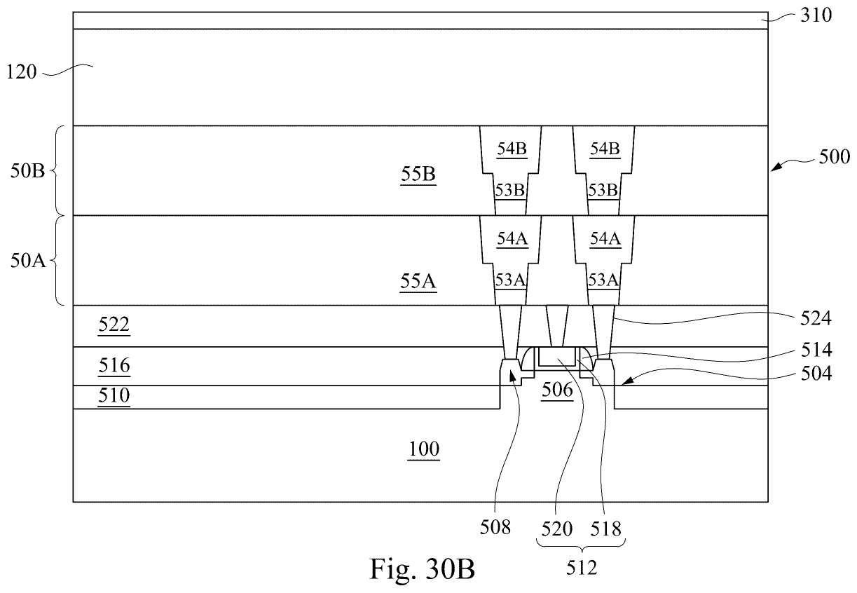

FIGS. 30A-38 illustrate intermediate stages of a method of forming a 3D IC structure in accordance with some embodiments. Although the cross-sectional views shown in FIGS. 30A-38 are described with reference to a method, it will be appreciated that the structures shown in FIGS. 30A-38 are not limited to the method but rather may stand alone separate of the method. Although FIGS. 30A-38 are described as a series of acts, it will be appreciated that these acts are not limiting in that the order of the acts can be altered in other embodiments, and the methods disclosed are also applicable to other structures. In other embodiments, some acts that are illustrated and/or described may be omitted in whole or in part.

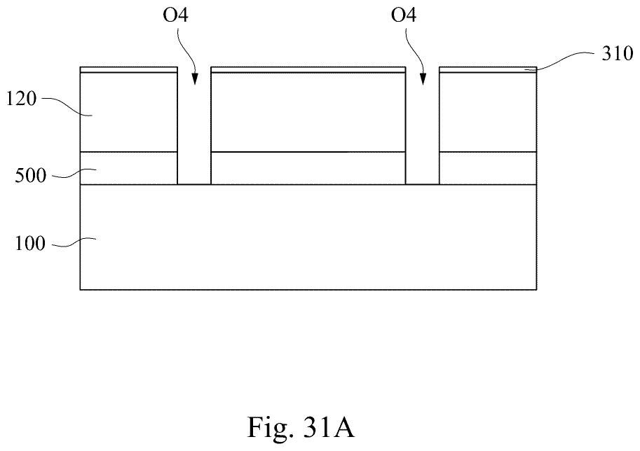

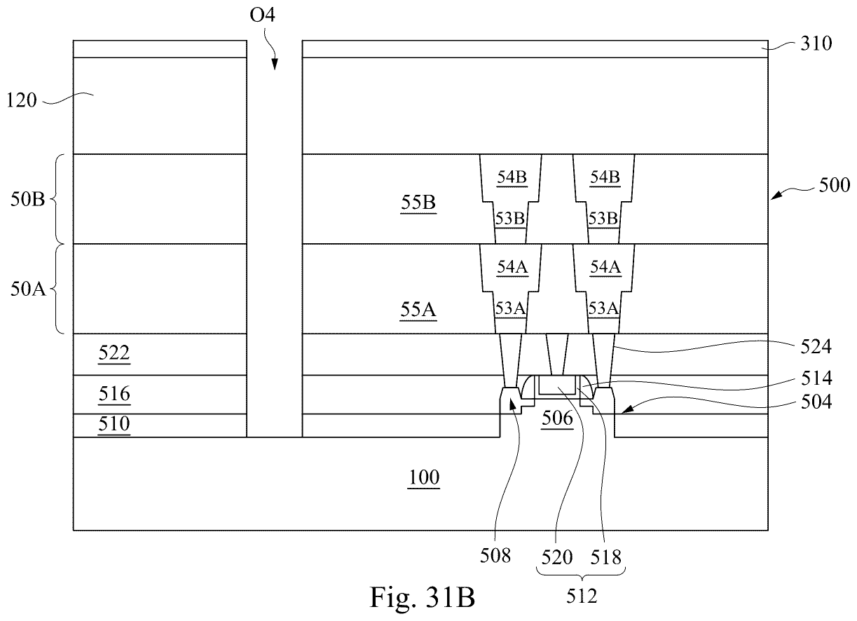

FIGS. 30A and 30B illustrate cross-sectional views of a structure after the step illustrated in FIGS. 11A and 11B. After the CMP process is completed, a spontaneous nucleation inhibition layer 310 is on the ILD layer 120, as illustrated in FIGS. 30A and 30B. A material of the spontaneous nucleation inhibition layer 310 is chosen in such a way that spontaneous nucleation of semiconductor material can be suppressed compared with the case where no spontaneous nucleation inhibition layer 310 is formed. The spontaneous nucleation inhibition layer 310 can thus aid in initiating nucleation of single-crystalline semiconductor material at the bottoms of holes O4 in the ILD layer 120 (as shown in FIGS. 31A and 31B), because the spontaneous nucleation of semiconductor material above the top surface of the ILD layer 120 is suppressed. In some embodiments, the spontaneous nucleation inhibition layer 310 includes, for example, silicon nitride (SiNₓ), aluminum oxide (AlO), silicon oxide (SiO₂) or other suitable materials that can suppress spontaneous nucleation of polysilicon. In some embodiments, the spontaneous nucleation inhibition layer 310 is formed using ALD, although other deposition techniques, such as CVD, PVD, PEALD, may be used.

In FIGS. 31A and 31B, holes O4 are etched in the ILD layer 120 and the lower-level circuit structure 500 until the substrate 100 is exposed at bottom of the holes O4. From top view the holes O4 are arranged equidistantly in rows and columns as discussed previously. Other details about forming the holes O4 are discussed previously with respect to FIGS. 12A-12B, and thus they are not repeated for the sake of brevity.

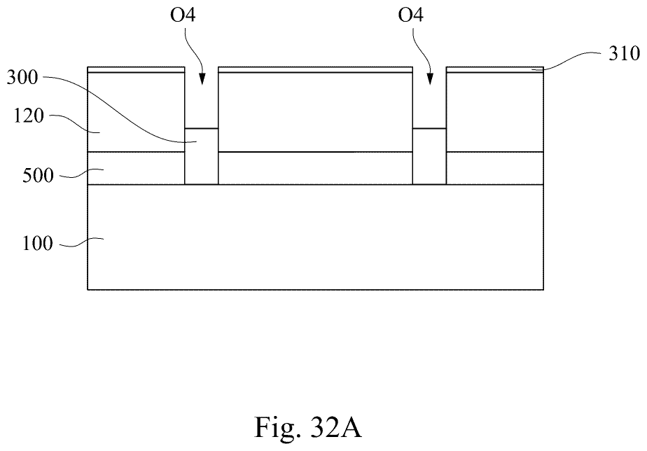

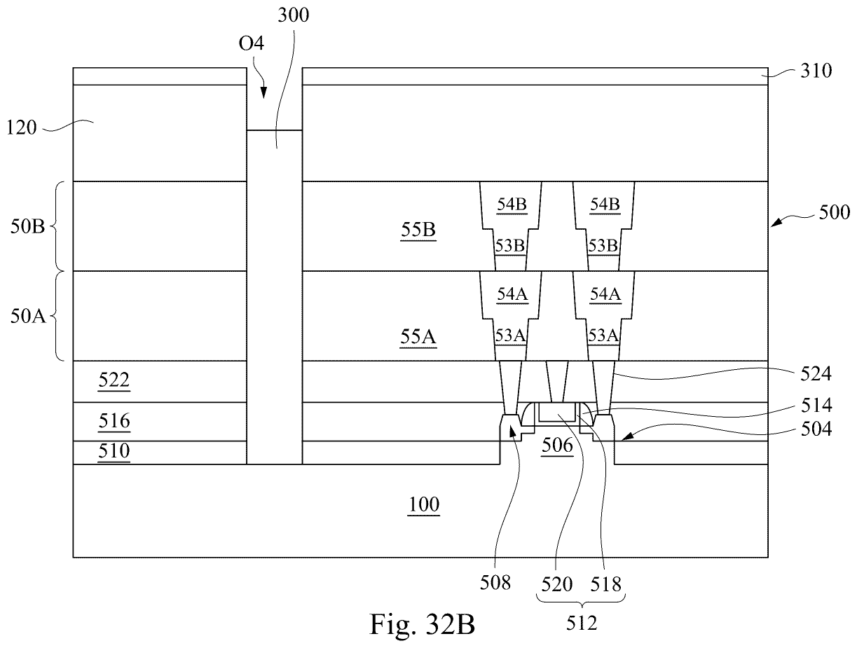

In FIGS. 32A and 32B, single-crystalline semiconductor pillars 300 are formed in the holes O4 in the lower-level circuit structure 500 and the ILD layer 120. The single-crystalline semiconductor pillars 300 are Si, Ge, or SiGe formed using low-temperature epitaxy growth at a temperature not higher than melting point of the semiconductor materials of the lower-level transistor 504. Therefore, epitaxy growth of the single-crystalline semiconductor pillars 300 has no or negligible the lower-level transistor 504. Because the semiconductor pillars 300 are formed using epitaxy growth, they can be interchangeably referred to as epitaxial pillars 300. Details about forming epitaxial pillars 300 are discussed previously with respect to FIGS. 13A-13B, and thus they are not repeated for the sake of brevity.

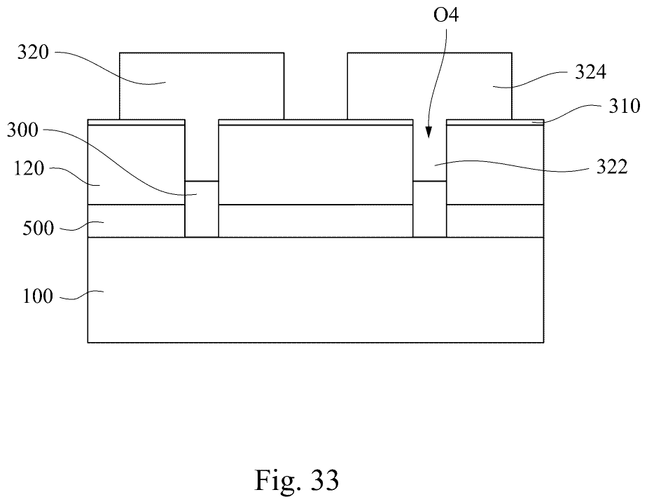

In FIG. 33, a semiconductor layer is deposited over the ILD layer 120 and patterned into a plurality of semiconductor islands 320 separated from each other. The semiconductor islands 320 are non-single crystalline, and are amorphous and/or polycrystalline. The semiconductor islands 320 include silicon (Si), germanium (Ge), silicon germanium (SiGe), or other semiconductor materials, and can be deposited using suitable deposition techniques same as depositing the semiconductor layer 130 discussed previously with respect to FIG. 4. Silicon atoms and/or germanium atoms of the semiconductor layer deposited on the ILD layer 120 tend to form an amorphous solid (i.e., non-crystalline solid) that lacks the long-range order of a crystal, because the dielectric material of the ILD layer 120 is amorphous in nature. Once the amorphous semiconductor layer is deposited, the amorphous semiconductor layer is patterned using suitable photolithography and etching techniques to form amorphous semiconductor islands 320.

The amorphous semiconductor islands 320 respectively overlap corresponding holes O4, and thus the semiconductor islands 320 each comprise an amorphous semiconductor plug 322 extending in the holes O4 in the ILD layer 120, and an amorphous semiconductor lateral portion 324 extending along a top surface of the ILD layer 120. Other details about the amorphous semiconductor islands 320 are discussed previously with respect to FIG. 23, and thus they are not repeated for the sake of brevity.

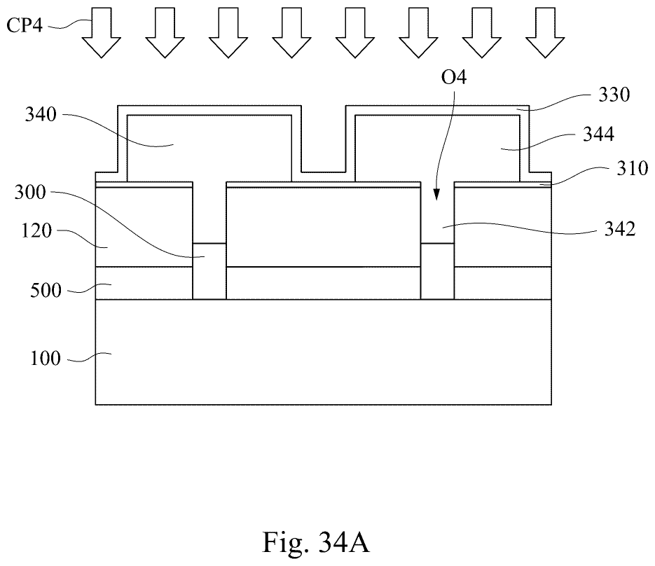

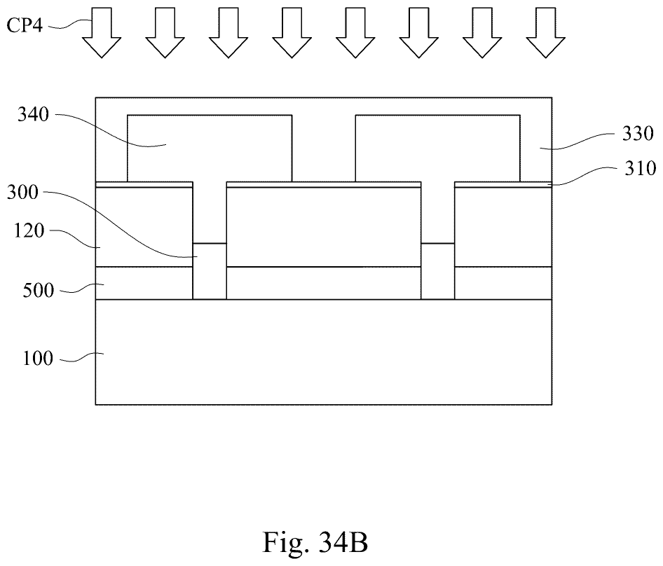

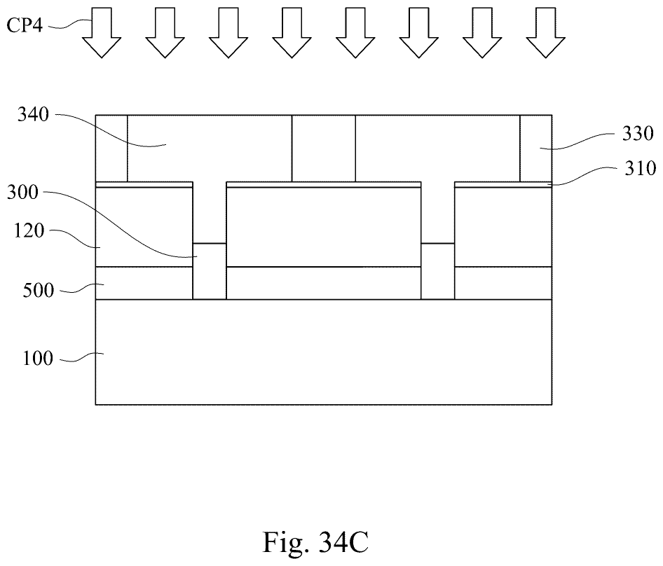

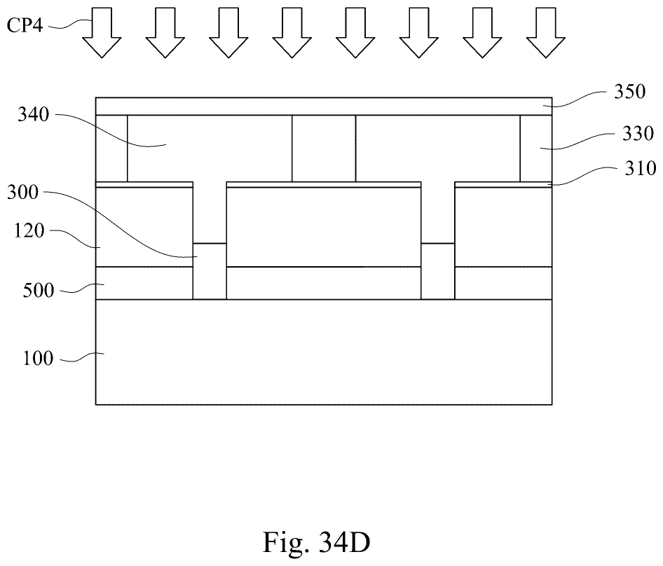

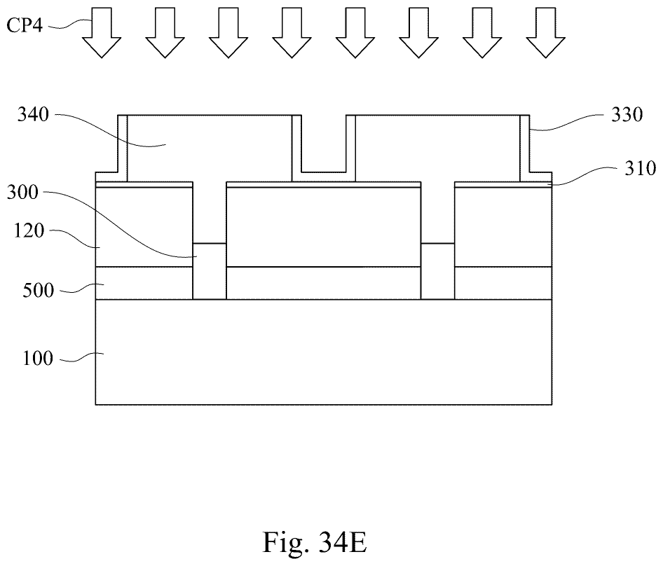

In FIG. 34A, a capping layer 330 is conformally deposited over the amorphous semiconductor islands 320. With the capping layer 330 in place, a crystallization process CP4 is performed to convert the amorphous semiconductor islands 320 into single-crystalline semiconductor islands 340. The capping layer 330 can serve to reduce heat dissipation rate from top surfaces and sidewalls of the amorphous semiconductor islands 320 in the cooling down stage of crystallization process CP4, which in turn improves the heat dissipation rate difference between the hole bottom and surfaces of the amorphous semiconductor islands 320, which in turn aids in initiating nucleation of single-crystalline semiconductor material almost only at the bottoms of the holes O3. The capping layer 330 can also serve to prevent adjacent semiconductor islands from merging during the crystallization process CP4, which in turn reduces the risk of forming grain boundaries and/or crystal defects such as dislocations.

In some embodiments, crystallization of the amorphous semiconductor islands 320 can be performed using, for example, a laser anneal, a rapid thermal anneal (RTA), a millisecond anneal (mSA), the like or combinations thereof, which raises temperature to a peak temperature higher than deposition temperature of the amorphous semiconductor islands 320. In greater detail, the amorphous semiconductor islands 320 can heated to a peak temperature higher than a melting point of the amorphous semiconductor islands 320 to melt the amorphous semiconductor islands 320 into a molten state, and then the molten amorphous semiconductor islands will be crystallized upon cooling. Because crystallization of the molten amorphous semiconductor islands takes place using the underlying single-crystalline epitaxial pillars 300 as seeds, the resultant crystallized semiconductor islands 340 will be single-crystalline instead of polycrystalline, and thus can be referred to as single-crystalline semiconductor islands 340.

Example crystallization process CP4 of the amorphous semiconductor islands 320 is performed by the laser anneal. The laser may be pulsed laser or a continuous wave laser that is directed toward top surfaces of the amorphous semiconductor islands 320. Because the amorphous semiconductor islands 320 are raised above the lower-level circuit structure 500 by significantly tall epitaxial pillars 300, the amorphous semiconductor islands 320 can be spaced apart from the lower-level circuit structure 500 by a distance that is long enough to create a significant temperature difference between the amorphous semiconductor islands 320 and the lower-level circuit structure 500 during the laser anneal, which in turn allows for melting the amorphous semiconductor islands 320 while not melting materials in the lower-level circuit structure 500 (e.g., semiconductor materials of FinFETs 504 as illustrated in FIG. 32B). As a result, the lower-level circuit structure 500 will not be damaged by the peak temperature of the laser anneal.

Once the laser anneal process stops, the molten amorphous semiconductor cools down and thus starts to crystallize into single-crystalline semiconductor islands 340. The crystallized semiconductor islands 340 each include a single-crystalline semiconductor plug 342 extending in a corresponding hole O4 in the ILD layer 120, and a single-crystalline semiconductor film 344 continuously spanning across the single-crystalline semiconductor plug 342. During cooling down, a heat dissipation rate in the ILD layer 120 decreases as a distance from the underlying lower-level circuit structure 500 increases, because the lower-level circuit structure 500 include multiple layers of metal lines and vias that dissipate heat at a faster rate than ambient gases, and because heat dissipation from the exposed surfaces of the molten amorphous semiconductor is reduced by the capping layer 330. The heat dissipation rate difference thus results in a lower temperature at bottoms of the holes O4 in the ILD layer 120 than above the top surface of the ILD layer 120, which in turn initiates nucleation of single-crystalline semiconductor material almost only at the bottoms of the holes O4, rather than initiating nucleation uniformly across the ILD layer 120. Moreover, the spontaneous nucleation of single-crystalline semiconductor material above the top surface of the ILD layer 120 can be further suppressed by the spontaneous nucleation inhibition layer 310, and thus the spontaneous nucleation inhibition layer 310 can further aid in initiating nucleation of single-crystalline semiconductor material at the bottoms of the holes O4.

In some embodiments, the molten amorphous semiconductor can be reheated before spontaneous nucleation on the ILD layer 120 begins, which in turn can aid in initiating nucleation at the bottoms of holes O4 in the ILD layer 120, because the spontaneous nucleation above the top surface of the ILD layer 120 can be suppressed by the reheating. Because the nucleation of semiconductor material begins from the bottom of holes O4, the single-crystalline epitaxial pillars 300 provide nucleation cites so that after cooling down the resultant semiconductor material becomes single-crystalline. As a result, the crystallized semiconductor islands 340 have no grain boundary.

FIG. 34B illustrates an alternative embodiment of the capping layer 330. In FIG. 34B, the capping layer 330 is formed to overfill spaces among the amorphous semiconductor islands 320, followed by performing the crystallization process CP4 to convert the amorphous semiconductor islands 320 into the single-crystalline semiconductor islands 340 with the capping layer 330 in place. In some embodiments, the capping layer 330 in FIG. 34B can be formed by CVD, spin-on coating, or other suitable deposition methods.

FIG. 34C illustrates an alternative embodiment of the capping layer 330. In FIG. 34C, the capping layer 330 is formed to fill spaces among the amorphous semiconductor islands 320 while leaving the top surfaces of amorphous semiconductor islands 320 exposed, followed by performing the crystallization process CP4 to convert the amorphous semiconductor islands 320 into the single-crystalline semiconductor islands 340 with the capping layer 330 in place. In some embodiments, the capping layer 330 in FIG. 34C can be formed by overfilling spaces among the amorphous semiconductor islands 320 by a dielectric material using a suitable deposition method, followed by performing a CMP process on the dielectric material to expose top surfaces of the amorphous semiconductor islands 320.

FIG. 34D illustrates an alternative embodiment of the present disclosure. In FIG. 34D, a sidewall capping layer 330 is formed to fill spaces among the amorphous semiconductor islands 320 and a top capping layer 350 is formed over the top surfaces of amorphous semiconductor islands 320, followed by performing the crystallization process CP4 to convert the amorphous semiconductor islands 320 into the single-crystalline semiconductor islands 340 with the sidewall capping layer 330 and top cap layer 350 in place. In some embodiments, the sidewall capping layer 330 in FIG. 34D can be formed by overfilling spaces among the amorphous semiconductor islands 320 by a first dielectric material using a suitable deposition method, followed by performing a CMP process on the first dielectric material to expose top surfaces of the amorphous semiconductor islands 320. The top capping layer 350 in FIG. 34D can be formed by depositing a second dielectric material over the amorphous semiconductor islands 320 and the sidewall capping layer 330, wherein the second dielectric material is different from the first dielectric material. For example, the second dielectric material may have a smaller thermal conductivity than the first dielectric material.

FIG. 34E illustrates an alternative embodiment of the capping layer 330. In FIG. 34E, the capping layer 330 is formed lining sidewalls of the amorphous semiconductor islands 320 while leaving the top surfaces of amorphous semiconductor islands 320 exposed, followed by performing the crystallization process CP4 to convert the amorphous semiconductor islands 320 into the single-crystalline semiconductor islands 340 with the capping layer 330 in place. In some embodiments, the capping layer 330 in FIG. 34E can be formed by depositing a conformal layer over the amorphous semiconductor islands 320 by a dielectric material using a suitable deposition method, followed by performing an angled dry etching process (e.g., plasma etching) on the dielectric material to expose top surfaces of the amorphous semiconductor islands 320, while leaving other portions of the dielectric material remaining on sidewalls of the amorphous semiconductor islands 320 and on top surface of the spontaneous nucleation inhibition layer 310 due to shadowing effect of the angled etching.

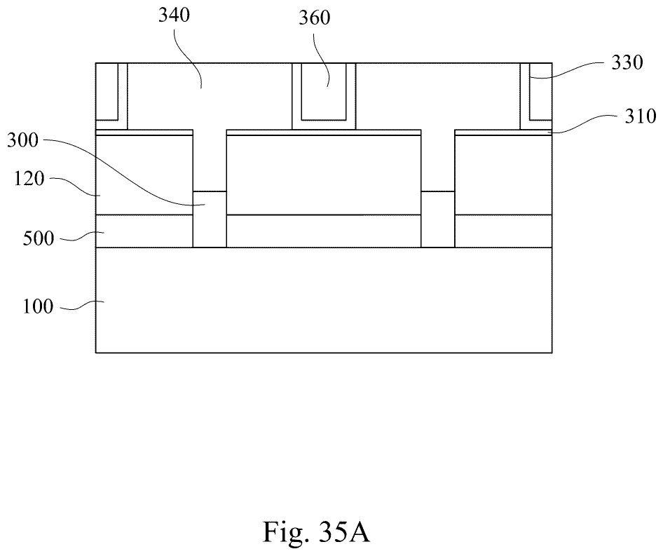

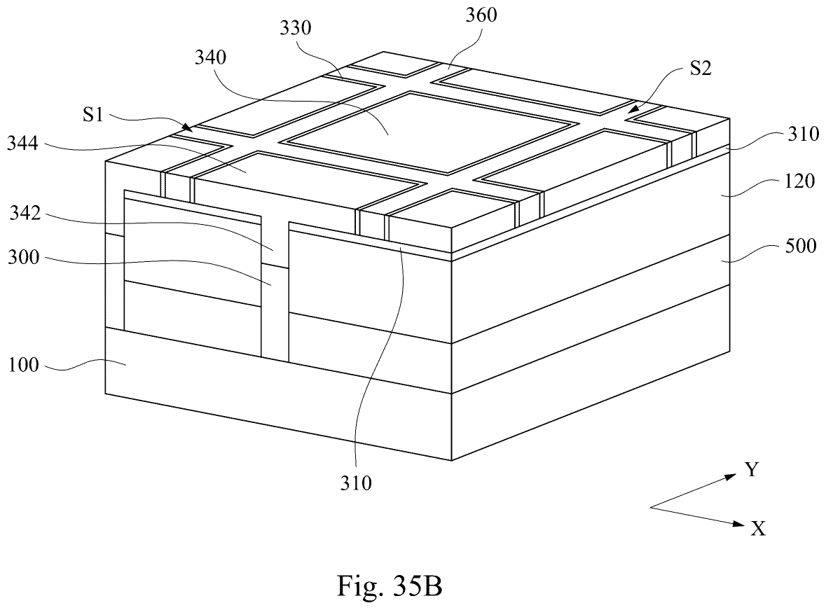

In FIGS. 35A and 35B, a filling dielectric 360 is formed to fill spaces among the single-crystalline semiconductor islands 340. This step may be performed subsequent to the step as shown in FIG. 34A or 34E. In some embodiments, the filling dielectric 360 is formed by first overfilling the spaces among the single-crystalline semiconductor islands 340 with a dielectric material, followed by planarizing the dielectric material by using, e.g., CMP, at least until top surfaces of the single-crystalline semiconductor islands 340 are exposed. As illustrated in the perspective view of FIG. 35B, the semiconductor islands 340 are arranged in rows and columns and have a quadrilateral top-view profile (e.g., rectangular top-view profile or square top-view profile), and the filling dielectric 360 fills X-directional “streets” S1 and Y-directional streets S2 among the semiconductor islands 340.

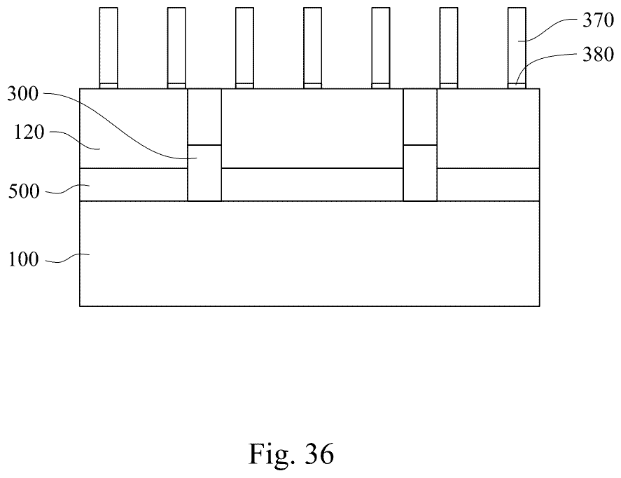

In FIG. 36, a plurality of single-crystalline semiconductor fins 370 are formed on the ILD layer 120 by patterning the single-crystalline semiconductor film 344 by using suitable photolithography and etching techniques. Details about forming the single-crystalline semiconductor fins 370 are discussed previously with respect to FIGS. 6A and 6B, and thus they are not repeated for the sake of brevity. In some embodiments, the spontaneous nucleation inhibition layer 310 is also patterned into separate spontaneous nucleation inhibition strips 380 underling the plurality of single-crystalline semiconductor fins 370. The spontaneous nucleation inhibition strips 380 may have a same top-view pattern as the single-crystalline semiconductor fins 370, because they are formed simultaneously in a same patterning process.

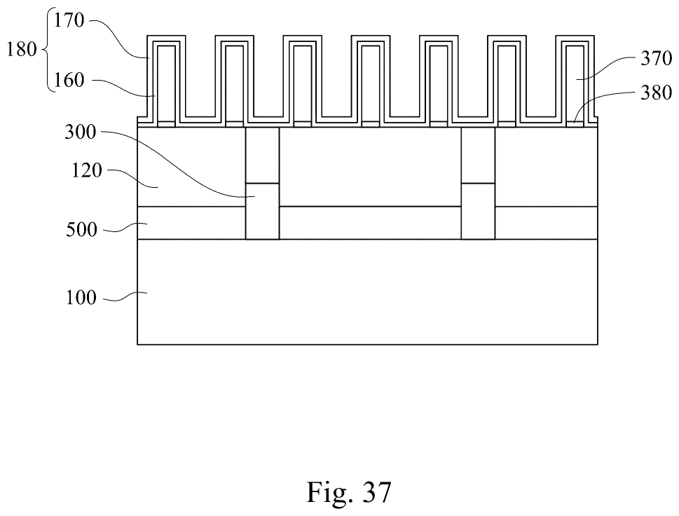

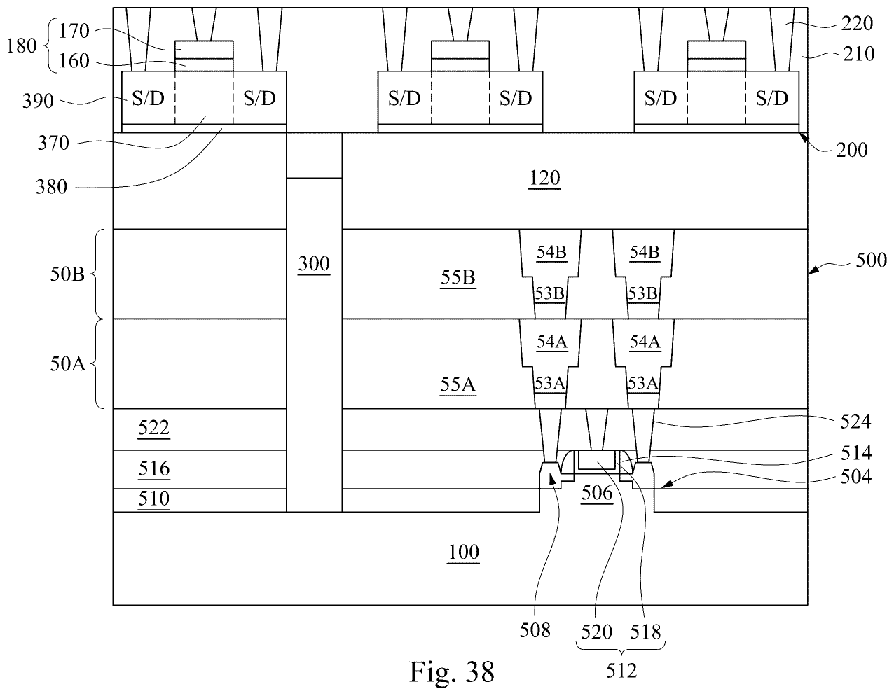

In FIG. 37, a gate dielectric layer 160 and a gate metal layer 170 are deposited in sequence over the upper-level fins 370, followed by patterning the gate dielectric layer 160 and the gate metal layer 170 into a HKMG gate structure 180 extending across channel regions of the upper-level fins 370, while leaving other regions of the upper-level fins 370 exposed. Other details about the HKMG gate structure 180 are discussed previously with respect to FIGS. 7A and 7B, and thus they are not repeated for the sake of brevity. Afterwards, a source/drain implantation process is performed to implant n-type or p-type dopants (e.g., As, P, B, In, or the like) on the exposed regions of the upper-level fins 370, and then an anneal is performed on the implanted regions of the upper-level fins 370 to activate the implanted dopants in each implanted regions, thus forming source/drain regions 390 on opposite sides of the HKMG gate structure 180. The resultant structure is shown in FIG. 38. The upper-level fins 370, the source/drain regions 390 in the upper-level fins 370, and the gate structure 180 can form upper-level FinFETs 200 on the ILD layer 120. In the illustrated embodiments, the transistors 200 are FinFETs. In some other embodiments, the transistors 200 are planar FETs, gate-all-around (GAA) FETs, nanosheet FETs, nanowire FETs, or other suitable FETs. In FIG. 38, an ILD layer 210 is formed over the upper-level FinFETs 200, and contacts 220 are formed in the ILD layer 210 to make electrical connections to the gate structures 180 and source/drain regions 390, respectively. Details about the ILD layer 210 and contacts 220 are discussed previously with respect to FIG. 9, and thus they are not repeated for the sake of brevity.

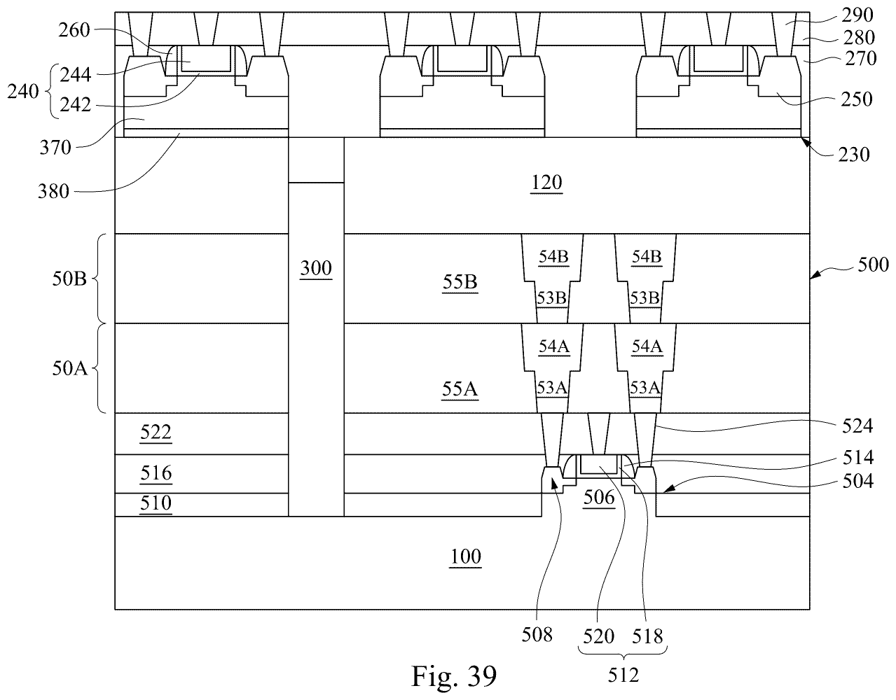

FIG. 39 illustrates an exemplary cross-sectional view of a 3D IC according to some other embodiments of the present disclosure. FIG. 39 shows substantially the same structure as FIG. 38, except that the 3D IC structure includes upper-level FinFETs 230 formed using a different process than the upper-level FinFETs 200 of FIG. 38. The upper-level FinFETs 230 are formed using a gate-last process, and each comprise a replacement HKMG gate structure 240 and epitaxial source/drain regions 250 on opposite sides of the HKMG gate structure 240. Details about the upper-level FinFETs 230 are formed using the gate-last process are discussed previously with respect to FIG. 10, and thus they are not repeated for the sake of brevity. ILD layers 270 and 280 are formed over the upper-level FinFETs 230, and contacts 290 are formed in the ILD layers 270, 280 to make electrical connections to the gate structures 240, and source/drain regions 250, respectively.

Based on the above discussions, it can be seen that the present disclosure offers advantages. It is understood, however, that other embodiments may offer additional advantages, and not all advantages are necessarily disclosed herein, and that no particular advantage is required for all embodiments. One advantage is that single-crystalline semiconductor can be formed above a lower-level circuit structure by crystallizing a non-single crystalline semiconductor material using substrate or epitaxial pillars grown from substrate as seeds. Another advantage is that the single-crystalline semiconductor can act as active regions of transistors (e.g., FinFETs, GAA FETs or planar FETs), thus forming a 3D IC having lower transistors at a lower level and higher transistors at a higher level.

In some embodiments, an IC structure includes a first transistor, a dielectric layer, a plurality of semiconductor pillars, a plurality of semiconductor plugs, a semiconductor structure, and a second transistor. The first transistor is formed on a substrate. The dielectric layer is above the first transistor. The semiconductor pillars extend from the substrate into the dielectric layer. The semiconductor plugs extend from a top surface of the dielectric layer into the dielectric layer to the plurality of semiconductor pillars. The semiconductor structure is disposed over the top surface of the dielectric layer. The second transistor is formed on the semiconductor structure. In some embodiments, the semiconductor pillars each have a top surface higher than a topmost position of the first transistor. In some embodiments, the first transistor is a FinFET having a fin, and the fin of the FinFET has a top surface lower than a top surface of the plurality of semiconductor pillars. In some embodiments, the semiconductor plugs are arranged in rows and columns from a top view. In some embodiments, the semiconductor pillars are arranged in rows and columns from a top view. In some embodiments, the semiconductor structure is a semiconductor fin on the top surface of the dielectric layer. In some embodiments, the semiconductor structure is a semiconductor fin, and the IC structure further comprises a spontaneous nucleation inhibition layer interposing the semiconductor fin and the dielectric layer. In some embodiments, the spontaneous nucleation inhibition layer has opposite sidewalls aligned with opposite sidewalls of the semiconductor fin. In some embodiments, the semiconductor pillars have a height greater than a height of the semiconductor plugs.

In some embodiments, an IC structure includes a first transistor, an interconnect structure, a semiconductor pillar, a dielectric layer, a semiconductor plug, and a second transistor. The first transistor is on a substrate. The interconnect structure is over the first transistor. The interconnect structure includes a conductive via vertically extending above the substrate and a conductive line laterally extending above the conductive via. The semiconductor pillar extends upwards from the substrate to a position higher than the conductive via and the conductive line. The dielectric layer laterally surrounds an upper portion of the semiconductor pillar. The semiconductor plug is inlaid in the dielectric layer and disposed over the semiconductor pillar. The second transistor is above the semiconductor plug. In some embodiments, the semiconductor plug has opposite sidewalls respectively offset from opposite sidewalls of the semiconductor pillar. In some embodiments, the semiconductor plug has opposite sidewalls respectively aligned with opposite sidewalls of the semiconductor pillar. In some embodiments, the semiconductor plug is silicon, germanium or silicon germanium.

In some embodiments, a method includes forming a semiconductor pillar extending from a substrate, forming a dielectric layer over the substrate, performing an etching process on the dielectric layer to form a hole in the dielectric layer, depositing a non-single crystalline semiconductor material in the hole and on the semiconductor pillar, performing an anneal process to crystallize the non-single crystalline semiconductor material into a single-crystalline semiconductor material, and forming a transistor on the single-crystalline semiconductor material. In some embodiments, the semiconductor pillar is formed by patterning the substrate. In some embodiments, the semiconductor pillar is formed by epitaxially growing a semiconductor material in the hole of the dielectric layer. In some embodiments, the anneal process is laser anneal. In some embodiments, the method further includes patterning the non-single crystalline semiconductor material into a plurality of non-single crystalline semiconductor islands before performing the anneal process. In some embodiments, the method further includes forming a capping layer over the non-single crystalline semiconductor anneal, wherein the annealing process is performed on the non-single crystalline semiconductor material with the capping layer in place. In some embodiments, the method further includes forming a spontaneous nucleation inhibition layer over the dielectric layer, wherein the non-single crystalline semiconductor material is deposited over the spontaneous nucleation inhibition layer.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An integrated circuit (IC) structure comprising:
a first transistor formed on a substrate;
a dielectric layer above the first transistor;
a plurality of semiconductor pillars extending from the substrate into the dielectric layer;
a plurality of semiconductor plugs extending from a top surface of the dielectric layer into the dielectric layer to the plurality of semiconductor pillars;
a semiconductor structure disposed over the top surface of the dielectric layer; and
a second transistor formed on the semiconductor structure.

2. The IC structure of claim 1, wherein the plurality of semiconductor pillars each have a top surface higher than a topmost position of the first transistor.

3. The IC structure of claim 1, wherein the first transistor is a FinFET having a fin, and the fin of the FinFET has a top surface lower than a top surface of the plurality of semiconductor pillars.

4. The IC structure of claim 1, wherein the plurality of semiconductor plugs are arranged in rows and columns from a top view.

5. The IC structure of claim 1, wherein the plurality of semiconductor pillars are arranged in rows and columns from a top view.

6. The IC structure of claim 1, wherein the semiconductor structure is a semiconductor fin on the top surface of the dielectric layer.

7. The IC structure of claim 1, wherein the semiconductor structure is a semiconductor fin, and the IC structure further comprises:
a spontaneous nucleation inhibition layer interposing the semiconductor fin and the dielectric layer.

8. The IC structure of claim 7, wherein the spontaneous nucleation inhibition layer has opposite sidewalls aligned with opposite sidewalls of the semiconductor fin.

9. The IC structure of claim 1, wherein the plurality of semiconductor pillars have a height greater than a height of the plurality of semiconductor plugs.

10. An IC structure comprising:
a first transistor on a substrate;
an interconnect structure over the first transistor, the interconnect structure comprising a conductive via vertically extending above the substrate and a conductive line laterally extending above the conductive via;
a semiconductor pillar extending upwards from the substrate to a position higher than the conductive via and the conductive line;
a dielectric layer laterally surrounding an upper portion of the semiconductor pillar;
a semiconductor plug inlaid in the dielectric layer and disposed over the semiconductor pillar; and
a second transistor above the semiconductor plug.

11. The IC structure of claim 10, wherein the semiconductor plug has opposite sidewalls respectively offset from opposite sidewalls of the semiconductor pillar.

12. The IC structure of claim 10, wherein the semiconductor plug has opposite sidewalls respectively aligned with opposite sidewalls of the semiconductor pillar.

13. The IC structure of claim 10, wherein the semiconductor plug is silicon, germanium or silicon germanium.

14. An IC structure comprising:
a multilevel interconnect structure over a substrate, the multilevel interconnect structure comprising a plurality of inter-metal dielectric (IMD) layers stacked one above another, and a plurality of metal structures in the plurality of IMD layers;
a semiconductor pillar protruding from the substrate through the plurality of IMD layers;
a semiconductor plug disposed over the semiconductor pillar, the semiconductor plug having sidewalls respectively offset from sidewalls of the semiconductor pillar;
an active region at a higher level than the semiconductor plug, the active region comprising a same material as the semiconductor plug; and
a transistor formed on the active region.

15. The IC structure of claim 14, wherein the active region non-overlaps with the semiconductor plug.

16. The IC structure of claim 14, wherein the semiconductor plug is embedded in a dielectric layer.

17. The IC structure of claim 16, wherein the active region is disposed over the dielectric layer.

18. The IC structure of claim 16, wherein the semiconductor pillar has a height greater than a height of the semiconductor plug.

19. The IC structure of claim 16, wherein the semiconductor pillar has a width greater than a width of the semiconductor plug.

20. The IC structure of claim 16, wherein the semiconductor pillar has a height greater than a height of the active region.
